(19) United States
(12) Patent Application Publication
(10) Pub. No.: US 2025/0088166 A1
(43) Pub. Date: Mar. 13, 2025

(54) BULK ACOUSTIC WAVE RESONATOR, MANUFACTURING METHOD THEREOF AND ELECTRONIC DEVICE

(71) Applicants: Beijing BOE Technology Development Co., Ltd., Beijing (CN); BOE Technology Group Co., Ltd., Beijing (CN)

(72) Inventor: Xiyuan WANG, Beijing (CN)

(21) Appl. No.: 18/580,099

(22) PCT Filed: Aug. 29, 2022
(86) PCT No.: PCT/CN2022/115414

§ 371 Date: Jan. 17, 2024

(51) Int. Cl. H03H 9/02; H03H 3/02; H03H 3/04; H03H 9/10; H03H 9/13; H03H 9/17

(52) U.S. Cl. CPC H03H 9/02102; H03H 3/04; H03H 9/1007; H03H 9/13; H03H 9/173; H03H 9/174; H03H 9/175; H03H 2003/023; H03H 2003/0407

(57) ABSTRACT

A bulk acoustic wave resonator, a method for manufacturing a bulk acoustic wave resonator and an electronic device are provided, and belongs to the field of communication technology. The bulk acoustic wave resonator includes: a first base substrate, a first electrode, a piezoelectric layer, and a second electrode; the first electrode is on the first base substrate; the piezoelectric layer is on a side of the first electrode away from the first base substrate; the second electrode is on a side of the piezoelectric layer away from the first electrode; a functional layer is formed on a side of the piezoelectric layer close to the first base substrate and/or on a side of the piezoelectric layer away from the first base substrate; the functional layer is made of a conductive material, and the functional layer is configured to suppress a temperature drift of the bulk acoustic wave resonator.

### TECHNICAL FIELD

The present disclosure relates to the field of communication technology, and in particular to a bulk acoustic wave resonator, a method for manufacturing a bulk acoustic wave resonator and an electronic device.

### BACKGROUND

In the field of mobile communications, the allocated total available frequency is in a narrow range, and there are many frequency bands used for the mobile communication, so that a spacing between adjacent frequency bands is narrow (about several MHz (megahertz) to tens of MHz), and a single frequency band has a narrow bandwidth (tens of MHz). Thus, a filter used in a mobile phone is required to have performance characteristics of a small in-band ripple, a large out-of-band rejection, and a good rectangularity. A conventional micro-strip filter has a large volume, an insufficient out-of-band rejection and a poor rectangularity and cannot meet the above requirement; a cavity filter has a large volume and cannot meet the above requirement; a dielectric filter has a large in-band insertion loss and a poor rectangularity and cannot meet the above requirement; an IPD (Integrated Passive Device) filter has a large in-band ripple and a poor rectangularity and cannot meet the above requirement.

A bulk acoustic wave resonator serves as an elementary unit of a structure of a bulk acoustic wave filter. The existing bulk acoustic wave resonator adopts a silicon wafer as a material of a substrate with a sandwich structure, including a first electrode, a piezoelectric material and a second electrode from bottom to top. An operating principle thereof is: a radio frequency signal enters into the resonator from an electrode at one end of the resonator, then is converted into an acoustic wave signal of mechanical vibration at an interface of the piezoelectric material and the metal electrode through an inverse piezoelectric effect; the acoustic wave signal is formed as a resonant standing wave with a certain frequency in the sandwich structure including the first electrode, the piezoelectric material and the second electrode; a frequency of the radio frequency signal is the same as a resonant frequency of the resonator; the acoustic wave signal is transmitted to the electrode at the other end of the resonator, and is converted into the radio frequency signal at the interface of the metal electrode and the piezoelectric material through a piezoelectric effect. The resonator has a fixed resonant frequency. When the frequency of the radio frequency signal is the same as the resonant frequency of the resonator, the conversion from the radio frequency signal to the acoustic wave signal to the radio frequency signal is high-efficiency; when the frequency of the radio frequency signal is not the same as the resonant frequency of the resonator, the conversion from the radio frequency signal to the acoustic wave signal to the radio frequency signal is low-efficiency, and most of the radio frequency signals cannot be transmitted through the resonator. That is, the resonator functions as a filter, which filters the radio frequency signals.

### SUMMARY

The present disclosure aims to solve at least one technical problem in the prior art, and provides a bulk acoustic wave resonator, a method for manufacturing a bulk acoustic wave resonator and an electronic device.

An embodiment of the present disclosure provides a bulk acoustic wave resonator, including: a first base substrate, a first electrode, a piezoelectric layer, and a second electrode; wherein the first electrode is on the first base substrate, the piezoelectric layer is on a side of the first electrode away from the first base substrate, and the second electrode is on a side of the piezoelectric layer away from the first electrode; wherein the bulk acoustic wave resonator further includes a functional layer on a side of the piezoelectric layer close to the first base substrate and/or on a side of the piezoelectric layer away from the first base substrate; a material of the functional layer includes a conductive material, and the functional layer is configured to suppress a temperature drift of the bulk acoustic wave resonator.

In the embodiment of the present disclosure, the material of the functional layer has a positive temperature coefficient, and is configured such that a temperature drift coefficient of the bulk acoustic wave resonator is in a range from −10 ppm/K to +10 ppm/K.

In the embodiment of the present disclosure, the material of the functional layer includes at least one of antimony, bismuth and gallium.

In the embodiment of the present disclosure, the functional layer has a hollowed-out pattern.

In the embodiment of the present disclosure, the functional layer is on a side of the piezoelectric layer close to the first base substrate, and the functional layer serves as the first electrode; or the functional layer is on a side of the piezoelectric layer away from the first base substrate, and the functional layer serves as the second electrode.

In the embodiment of the present disclosure, the functional layer is on a side of the piezoelectric layer close to the first base substrate, and the functional layer is between the first electrode and the piezoelectric layer; or the functional layer is on a side of the piezoelectric layer away from the first base substrate, and the functional layer is located between the second electrode and the piezoelectric layer.

In the embodiment of the present disclosure, the functional layer is on a side of the piezoelectric layer close to the first base substrate, and the functional layer is between the first electrode and the first base substrate; or the functional layer is on a side of the piezoelectric layer away from the first base substrate, and the functional layer is on a side of the second electrode away from the first base substrate.

In the embodiment of the present disclosure, the first electrode includes a first sub-electrode and a second sub-electrode arranged sequentially in a direction away from the first base substrate, and the functional layer is on a side of the piezoelectric layer close to the first base substrate, and the functional layer is between the first sub-electrode and the second sub-electrode.

In the embodiment of the present disclosure, the second electrode includes a third sub-electrode and a fourth sub-electrode arranged sequentially in a direction away from the first base substrate, and the functional layer is on a side of the piezoelectric layer away from the first base substrate, and the functional layer is between the third sub-electrode and the fourth sub-electrode.

In the embodiment of the present disclosure, the first base substrate includes a first cavity penetrating through the first base substrate in a thickness direction of the first base substrate; the first base substrate includes a first surface and a second surface opposite to each other in the thickness direction of the first base substrate; the first cavity includes a first opening and a second opening opposite to each other; and the first opening is in the first surface, and the second opening is in the second surface; and an orthographic projection of the first electrode on the second surface covers an orthographic projection of the first opening on the second surface.

In the embodiment of the present disclosure, the first base substrate includes a first groove; the first base substrate includes a first surface and a second surface opposite to each other in a thickness direction of the first base substrate; the first groove includes a third opening; and the third opening is in the first surface, the first electrode is on the first surface; and an outline of an orthographic projection of the third opening on the second surface is within an outline of an orthographic projection of the first electrode on the second surface.

In the embodiment of the present disclosure, the bulk acoustic wave resonator further includes at least one mirror structure between the first electrode and the first base substrate; wherein each of the at least one mirror structure includes a first sub-structure layer and a second sub-structure layer sequentially arranged in a direction away from the first base substrate, and an acoustic impedance of a material of the first sub-structure layer is greater than that of a material of the second sub-structure layer.

In the embodiment of the present disclosure, the bulk acoustic wave resonator further includes an encapsulation layer on a side of the second electrode away from the first base substrate, wherein the encapsulation layer covers the first electrode, the piezoelectric layer, the second electrode and the functional layer.

An embodiment of the present disclosure provides a method for manufacturing a bulk acoustic wave resonator, including: sequentially forming a first electrode, a piezoelectric layer and a second electrode on a first base substrate, wherein orthographic projections of any two of the first electrode, the piezoelectric layer and the second electrode on the first base substrate at least partially overlap with each other; wherein the method further includes: forming a functional layer on a side of the piezoelectric layer close to the first base substrate and/or on a side of the piezoelectric layer away from the first base substrate; a material of the functional layer includes a conductive material, and the functional layer is configured to suppress a temperature drift of the bulk acoustic wave resonator.

In the embodiment of the present disclosure, the material of the functional layer has a positive temperature coefficient, and is configured such that a temperature drift coefficient of the bulk acoustic wave resonator is in a range from −10 ppm/K to +10 ppm/K.

In the embodiment of the present disclosure, the material of the functional layer includes at least one of antimony, bismuth and gallium.

In the embodiment of the present disclosure, the functional layer has a hollowed-out pattern.

In the embodiment of the present disclosure, the method includes the forming the functional layer on a side of the piezoelectric layer close to the first base substrate; the functional layer and the first electrode are formed by a single patterning process, and the functional layer serves as the first electrode; or the method includes the forming the functional layer on a side of the piezoelectric layer away from the first base substrate; the functional layer and the second electrode are formed by a single patterning process, and the functional layer serves as the second electrode.

In the embodiment of the present disclosure, the method includes the forming the functional layer on a side of the piezoelectric layer close to the first base substrate, and the forming the functional layer is between the forming the first electrode and the forming the piezoelectric layer; or the method includes the forming the functional layer on a side of the piezoelectric layer away from the first base substrate, and the forming the functional layer is between the forming the second electrode and the forming the piezoelectric layer.

In the embodiment of the present disclosure, the method includes the forming the functional layer on a side of the piezoelectric layer close to the first base substrate, and the forming the functional layer is before the forming the first electrode; or the method includes the forming the functional layer on a side of the piezoelectric layer away from the first base substrate, and the forming the functional layer is after the forming the second electrode.

In the embodiment of the present disclosure, the forming the first electrode includes sequentially forming a first sub-electrode and a second sub-electrode in a direction away from the first base substrate; the method includes the forming the functional layer on a side of the piezoelectric layer close to the first base substrate, and the forming the functional layer is between the forming the first sub-electrode and the forming the second sub-electrode.

In the embodiment of the present disclosure, the forming the second electrode includes sequentially forming a third sub-electrode and a fourth sub-electrode in a direction away from the first base substrate; the method includes the forming the functional layer on a side of the piezoelectric layer away from the first base substrate, and the forming the functional layer is between the forming the third sub-electrode and the forming the fourth sub-electrode.

In the embodiment of the present disclosure, the method further includes: forming a first cavity penetrating through the first base substrate in a thickness direction of the first base substrate by performing a treatment on the first base substrate; wherein the first base substrate includes a first surface and a second surface opposite to each other in the thickness direction of the first base substrate; the first cavity includes a first opening and a second opening opposite to each other; and the first opening is in the first surface, and the second opening is in the second surface; and an orthographic projection of the first electrode on the second surface covers an orthographic projection of the first opening on the second surface.

In the embodiment of the present disclosure, the method further includes: forming a first groove by performing a treatment on the first base substrate; wherein the first base substrate includes a first surface and a second surface opposite to each other in a thickness direction of the first base substrate; the first groove includes a third opening; and the third opening is in the first surface, the first electrode is on the first surface; and an outline of an orthographic projection of the third opening on the second surface is within an outline of an orthographic projection of the first electrode on the second surface.

In the embodiment of the present disclosure, before the forming the first electrode, the method further includes: forming at least one mirror structure on the first base substrate such that each of the at least one mirror structure includes a first sub-structure layer and a second sub-structure layer sequentially arranged in a direction away from the first base substrate, and an acoustic impedance of a material of the first sub-structure layer is greater than that of a material of the second sub-structure layer.

An embodiment of the present disclosure provides an electronic device, which includes the bulk acoustic wave resonator of any one of the embodiments described above.

### BRIEF DESCRIPTION OF DRAWINGS

FIG. 1 is a schematic diagram of a back-etched bulk acoustic wave resonator.

FIG. 2a is a schematic diagram of a film bulk acoustic wave resonator.

FIG. 2b is a schematic diagram of a film bulk acoustic wave resonator.

FIG. 3 is a schematic diagram of a solid mounted bulk acoustic wave resonator.

FIG. 4 is a schematic diagram of a bulk acoustic wave resonator of a first example of an embodiment of the present disclosure.

FIG. 5 is a flow chart illustrating how to manufacture a bulk acoustic wave resonator shown in FIG. 4.

FIG. 6 is a schematic diagram of a bulk acoustic wave resonator of a second example of an embodiment of the present disclosure.

FIG. 7 is a schematic diagram of a bulk acoustic wave resonator of a third example of an embodiment of the present disclosure.

FIG. 8 is a schematic diagram of a bulk acoustic wave resonator of a fourth example of an embodiment of the present disclosure.

FIG. 9 is a flow chart illustrating how to manufacture a bulk acoustic wave resonator shown in FIG. 8.

FIG. 10 is a schematic diagram of a bulk acoustic wave resonator of a fifth example of an embodiment of the present disclosure.

FIG. 11 is a schematic diagram of a bulk acoustic wave resonator of a sixth example of an embodiment of the present disclosure.

FIG. 12 is a schematic diagram of a bulk acoustic wave resonator of a seventh example of an embodiment of the present disclosure.

FIG. 13 is a schematic diagram of a bulk acoustic wave resonator of an eighth example of an embodiment of the present disclosure.

FIG. 14 is a flow chart illustrating how to manufacture a bulk acoustic wave resonator shown in FIG. 13.

FIG. 15 is a schematic diagram of a bulk acoustic wave resonator of a ninth example of an embodiment of the present disclosure.

FIG. 16 is a schematic diagram of a bulk acoustic wave resonator of a tenth example of an embodiment of the present disclosure.

FIG. 17 is a schematic diagram of a bulk acoustic wave resonator of an eleventh example of an embodiment of the present disclosure.

FIGS. 18 to 50 are schematic diagrams of an exemplary bulk acoustic wave resonator of an embodiment of the present disclosure.

### DETAIL DESCRIPTION OF EMBODIMENTS

In order to enable one of ordinary skill in the art to better understand the technical solutions of the present disclosure, the present disclosure will be described in further detail with reference to the accompanying drawings and the detailed description.

Unless defined otherwise, technical or scientific terms used herein shall have the ordinary meaning as understood by one of ordinary skill in the art to which the present disclosure belongs. The terms “first”, “second”, and the like used in the present disclosure are not intended to indicate any order, quantity, or importance, but rather are used for distinguishing one element from another. Further, the term “a”, “an”, “the”, or the like used herein does not denote a limitation of quantity, but rather denotes the presence of at least one element. The term “comprising”, “including”, or the like, means that the element or item preceding the term contains the element or item listed after the term and its equivalent, but does not exclude other elements or items. The term “connected”, “coupled”, or the like is not limited to a physical or mechanical connection, but may include an electrical connection, whether a direct or indirect connection. The terms “upper”, “lower”, “left”, “right”, and the like are used only for indicating relative positional relationships, and when the absolute position of an object being described is changed, the relative positional relationships may also be changed accordingly.

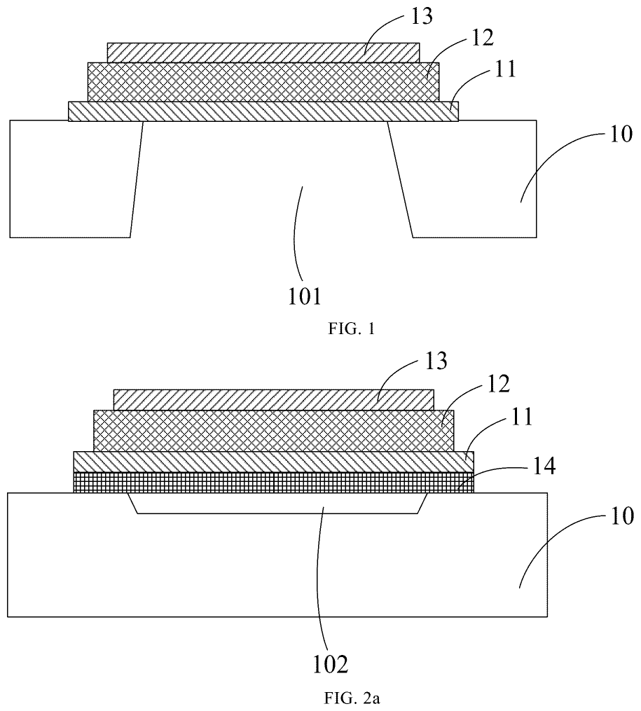

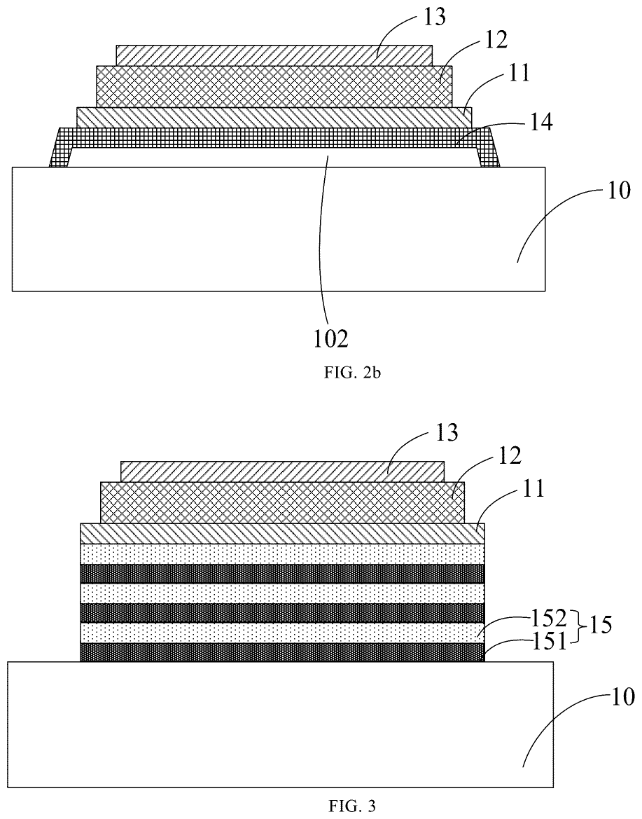

As shown in FIGS. 1, 2a, 2b and 3, in order to reduce an insertion loss of a bulk acoustic wave resonator in a filtering process, it is necessary to limit an acoustic wave signal in a piezoelectric layer 12 between a first electrode 11 and a second electrode 13 as much as possible, to prevent the acoustic wave signal from diffusing out, so that acoustic wave reflectors are usually provided on the upper and lower surfaces of the resonator. A reflector is generally provided on the upper surface and is made of an air medium with a low acoustic impedance. Depending on the acoustic wave reflectors provided on the lower surface, the bulk acoustic wave resonators are divided into three major classes, that is, a back-etched bulk acoustic wave resonator as shown in FIG. 1; a film bulk acoustic wave resonator (abbreviated as FBAR) as shown in FIGS. 2a and 2b; and a solid mounted resonator (abbreviated as SMR) as shown in FIG. 3. In the FBAR, under the first electrode, a first groove 102 is formed on the first base substrate 10 by etching as an air gap, and then the first electrode is supported by an isolation layer 14, as shown in FIG. 2a. Alternatively, the first groove 102 is formed as the air gap in the isolation layer 14, as shown in FIG. 2b. In the SMR, high acoustic impedance layers 151 and low acoustic impedance layers 152 are alternately and repeatedly stacked under the first electrode 11 as an acoustic mirror 15. In the back-etched bulk acoustic wave resonator, under the first electrode 11, a first cavity 101 is formed in the first base substrate 10 as an air layer by forming a cavity by deep etching back on the back of a silicon substrate.

The inventor finds that no matter any one of the above bulk acoustic wave resonators, the piezoelectric layer is made of C-axis aligned crystalline AIN having an in-plane lattice constant which increases with the increase of temperature, and an out-of-plane lattice constant decreases with the increase of temperature, which causes a propagation speed of acoustic waves to decrease. It can be known from a qualitative formula that a resonant frequency of the bulk acoustic wave resonator will decrease, i.e., a temperature drift will occur.

In order to solve the above problem, in the bulk acoustic wave resonator of the embodiment of the present disclosure, a functional layer is formed on a side of the piezoelectric layer close to the first base substrate and/or on a side of the piezoelectric layer away from the first base substrate, for resisting the temperature drift, that is, suppressing the temperature drift of the piezoelectric layer. The functional layer is made of a conductive material. In the embodiment of the present disclosure, the functional layer made of the conductive material is formed on a side of the piezoelectric layer close to the first base substrate and/or on a side of the piezoelectric layer away from the first base substrate, for resisting the temperature drift, so that a temperature coefficient of the bulk acoustic wave resonator is adjusted; and the functional layer is made of the conductive material, so that the piezoelectric effect and the inverse piezoelectric effect can be effectively introduced and thus, the quality factor and the performance of the device are improved.

A bulk acoustic wave resonator and a method for manufacturing a bulk acoustic wave resonator according to the embodiments of the present disclosure are described below with reference to specific examples. It should be noted that the bulk acoustic wave resonator in the embodiment of the present disclosure may be any one of a back-etched bulk acoustic wave resonator, a thin bulk acoustic wave resonator, and a solid mounted bulk acoustic wave resonator; or may be other type of the bulk acoustic wave resonator. In the following examples, only the back-etched bulk acoustic wave resonator is taken as an example for description.

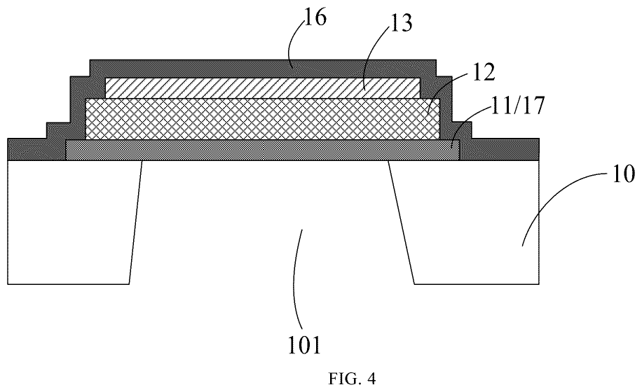

In a first example: FIG. 4 is a schematic diagram of a bulk acoustic wave resonator of a first example of an embodiment of the present disclosure. As shown in FIG. 4, the bulk acoustic wave resonator includes a first base substrate 10, and a first electrode 11, a piezoelectric layer 12, and a second electrode 13 which are sequentially disposed on the first base substrate 10, and the first electrode 11 further serves as a functional layer 17. Orthographic projections of any two of the first electrode 11, the piezoelectric layer 12 and the second electrode 13 on the first base substrate 10 at least partially overlap with each other. An encapsulation layer 16 may further be provided on a side of the second electrode 13 away from the first base substrate 10. The first base substrate 10 has a first cavity penetrating through the first base substrate 10 in a thickness direction of the first base substrate 10. The first base substrate 10 includes a first surface (upper surface) and a second surface (lower surface) which are oppositely disposed in the thickness direction of the first base substrate 10, and the first cavity includes a first opening 101 formed in the first surface and a second opening formed in the second surface. The first electrode 11 is disposed on the first surface, and an orthographic projection of the first electrode 11 on a plane of the second surface (a plane where the second surface is located) covers an orthographic projection of the first opening 101 on the plane of the second surface.

In this example, the first electrode 11 further serves as the functional layer 17, that is, the first electrode 11 has a function of resisting temperature drift, and the first electrode 11 is attached to the piezoelectric layer 12, so as to reduce the temperature drift coefficient of the device as much as possible. The bulk acoustic wave resonator having such the structure has a high resonant frequency, a low cost, a small volume, a low insertion loss, a small in-band ripple, a large out-of-band rejection and a good rectangularity. The bulk acoustic wave resonator may be widely applied to various frequency bands greater than 1 GHz in the field of mobile communication, and can effectively filter out low-frequency interference signals and higher harmonics thereof in the ground environment. The signal quality of the mobile communication is improved.

In some examples, a material of the first electrode 11, i.e., the functional layer 17, has a positive temperature coefficient, which changes the temperature drift coefficient of the bulk acoustic wave resonator from −30 ppm/K to be in a range from −10 ppm/K to +10 ppm/K.

Further, the material of the first electrode 11 includes, but is not limited to, metal or alloy materials. For example, the material of the first electrode 11 is any one of antimony, bismuth, and gallium, or an alloy material of at least two of these. The piezoelectric effect and the inverse piezoelectric effect can be effectively introduced by selecting the proper material of the first electrode 11, so that the quality factor of the bulk acoustic wave resonator is improved, and the performance of the device is improved.

In some examples, a material of the first base substrate 10 is preferably glass, and may alternatively be Si, sapphire, SiC, GaAs, GaN, InP, BN, ZnO, etc. A thickness of the first base substrate 10 is in a range of 0.1 μm to 10 mm.

In some examples, a material of the piezoelectric layer 12 is preferably hBN, and may alternatively be cBN, wBN. Alternatively, the material of the piezoelectric layer 12 may be selected from AlN, ZnO, PZT, GaN, InN, CdS, CdSe, ZnS, CdTe, ZnTe, GaAs, GaSb, InAs, InSb, GaSe, GaP, AlP, quartz crystal, LiTaO3, LiNbO3, La3Ga5SiO14, BaTiO3, PbNb2O6, PBLN, LiGaO3, LiGeO3, TiGeO3, PbTiO3, PbZrO3, PVDF, etc. The piezoelectric layer 12 in the present embodiment may be one of the piezoelectric materials described above, or may be a stack of the above piezoelectric materials. A thickness of the piezoelectric layer 12 is in a range of 10 nm to 100 μm.

In some examples, a material of the second electrode 13 may be selected from Cu, Al, Mo, Co, Ag, Ti, Pt, Ru, W, Au, or an alloy material of any of the above metals. A thickness of the second electrode 13 is in a range of 1 nm to 10 μm.

In some examples, a material of the encapsulation layer 16 is preferably an organic compound capable of blocking moisture and oxygen, such as polyimide, epoxy, or the like. Alternatively, the material of the encapsulation layer 16 may be an inorganic material such as SiNₓ, Al₂O₃, or the like. The encapsulation layer 16 may be a single layer of material or may be a stack of materials.

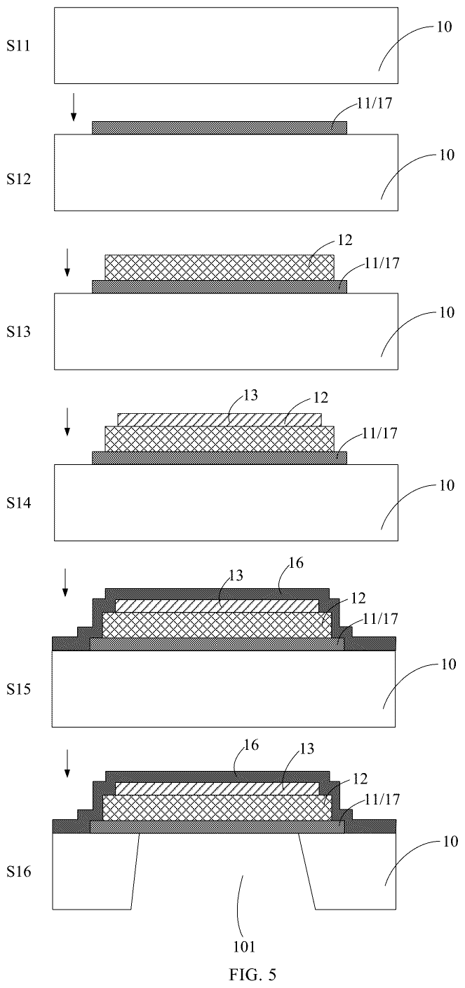

For the bulk acoustic wave resonator shown in FIG. 4, an embodiment of the present disclosure provides a method for manufacturing a bulk acoustic wave resonator. FIG. 5 is a flow chart of manufacturing a bulk acoustic wave resonator shown in FIG. 4. As shown in FIG. 5, the manufacturing method may specifically include the following steps S11 to S16.

At the step S11, a first base substrate 10 is provided.

In this step, the first base substrate 10 may be cleaned and then dried by air knife.

At the step S12, a first electrode 11 is formed on the first base substrate 10.

In some examples, the step S12 may include depositing a first conductive film on the first base substrate 10, preferably by direct current magnetron sputtering (alternatively, radio frequency magnetron sputtering), alternatively by pulsed laser sputtering (PLD), molecular beam epitaxy (MBE), thermal evaporation, electron beam evaporation. Processes including coating glue (or spraying glue), pre-baking, exposing, developing and post-baking are performed on the first conductive film. Finally, an etching process is performed, preferably a wet etching process, or alternatively a dry etching process, to form a pattern including the first electrode 11.

At the step S13, a piezoelectric layer 12 is formed on the first base substrate 10 after the above steps.

In some examples, as an example, a material of the piezoelectric layer 12 is hBN, in step S13, an orientation growth of the piezoelectric material may be performed firstly, preferably by radio frequency magnetron sputtering, and a target material is hBN. A hBN oriented film rich in nitrogen vacancies (whose the piezoelectric property is much better than that of BN without nitrogen vacancies) is formed by controlling an air pressure and a temperature of Ar and N2 and a time and temperature of post-annealing in the deposition, and preferably the growth orientation is (100), and may alternatively be (001) and (111). The film deposition method may be selected from pulsed laser sputtering (PLD), molecular beam epitaxy (MBE), metal organic chemical vapor deposition (MOCVD), plasma enhanced chemical vapor deposition (PECVD), and the like. The piezoelectric layer 12 is subjected to a photolithography process including coating glue (or spraying glue), pre-baking, exposing, developing and post-baking. Finally, the piezoelectric material layer is etched to form a pattern of the piezoelectric layer 12; a preferred etching process may be a wet etching process or a dry etching process.

At the step S14, a second electrode 13 is formed on the first base substrate 10 after the above steps.

In some examples, step S14 may include depositing a second conductive film, preferably by direct current magnetron sputtering (alternatively, radio frequency magnetron sputtering), alternatively by pulsed laser sputtering (PLD), molecular beam epitaxy (MBE), thermal evaporation, electron beam evaporation. Processes including coating glue (or spraying glue), pre-baking, exposing, developing and post-baking are performed on the second conductive film. Finally, an etching process is performed, preferably a wet etching process, or alternatively a dry etching process, to form the second electrode 13. The second conductive film formed on a hole wall is thinner, which is not favorable for low-loss transmission of radio frequency signals, so that the second conductive film in the first connecting via 121 may be thickened by an electroplating process, and then a pattern of the second electrode 13 is formed.

At the step S15, an encapsulation layer 16 is formed on the first base substrate 10 after the above steps.

In some examples, a material of the encapsulation layer 16 may be an organic material polyimide. In this case, step S15 may include performing liquid coating of the organic material, such as spin coating, spraying, ink-jet printing, or transferring or the like, and then performing a heat curing process to form a pattern of the encapsulation layer 16.

At the step S16, the first base substrate 10 is turned over to form a first cavity 101 after the above steps.

In some examples, the first base substrate 10 may be a glass substrate, in which case, the step S16 may include forming the first cavity 101 penetrating through the first base substrate 10 in a thickness direction of the first base substrate 10 by bombarding the first base substrate 10 using a laser-induced method and then HF etching. The first cavity 101 has a cross-section which is substantially perpendicular to the glass surface at an angle of approximately 90°. The first cavity 101 may be formed by wet etching or dry etching for other non-glass substrates.

In a second example: FIG. 6 is a schematic diagram of a bulk acoustic wave resonator of a second example of an embodiment of the present disclosure. As shown in FIG. 6, the bulk acoustic wave resonator includes a first base substrate 10, and a first electrode 11, a piezoelectric layer 12, and a second electrode 13 which are sequentially disposed on the first base substrate 10, and the second electrode 13 further serves as a functional layer 17. Orthographic projections of any two of the first electrode 11, the piezoelectric layer 12 and the second electrode 13 on the first base substrate 10 at least partially overlap with each other. An encapsulation layer 16 may further be provided on a side of the second electrode 13 away from the first base substrate 10. The first base substrate 10 has a first cavity penetrating through the first base substrate 10 in a thickness direction of the first base substrate 10. The first base substrate 10 includes a first surface (upper surface) and a second surface (lower surface) which are oppositely disposed in the thickness direction of the first base substrate 10, and the first cavity includes a first opening 101 formed in the first surface and a second opening formed in the second surface. The first electrode 11 is disposed on the first surface, and an orthographic projection of the first electrode 11 on a plane of the second surface (a plane where the second surface is located) covers an orthographic projection of the first opening 101 on the plane of the second surface.

In this example, the second electrode 13 further serves as the functional layer 17, that is, the second electrode 13 has a function of resisting temperature drift, and the second electrode 13 is attached to the piezoelectric layer 12, so as to reduce the temperature drift coefficient of the device as much as possible, even to achieve a zero temperature drift coefficient. The bulk acoustic wave resonator having such the structure has a high resonant frequency, a low cost, a small volume, a low insertion loss, a small in-band ripple, a large out-of-band rejection and a good rectangularity. The bulk acoustic wave resonator may be widely applied to various frequency bands greater than 1 GHz in the field of mobile communication, and can effectively filter out low-frequency interference signals and higher harmonics thereof in the ground environment. The signal quality of the mobile communication is improved.

In some examples, a material of the second electrode 13, i.e., the functional layer 17, has a positive temperature coefficient, which changes the temperature drift coefficient of the bulk acoustic wave resonator from −30 ppm/K to be in a range from −10 ppm/K to +10 ppm/K.

Further, the material of the second electrode 13 includes, but is not limited to, metal or alloy materials. For example, the material of the second electrode 13 is any one of antimony, bismuth, and gallium, or an alloy material of at least two of these. The piezoelectric effect and the inverse piezoelectric effect can be effectively introduced by selecting the proper material of the second electrode 13, so that the quality factor of the bulk acoustic wave resonator is improved, and the performance of the device is improved.

In some examples, a material of the first base substrate 10 is preferably glass, and may alternatively be Si, sapphire, SiC, GaAs, GaN, InP, BN, ZnO, etc. A thickness of the first base substrate 10 is in a range of 0.1 μm to 10 mm.

In some examples, a material of the piezoelectric layer 12 is preferably hBN, and may alternatively be cBN, wBN. Alternatively, the material of the piezoelectric layer 12 may be selected from AlN, ZnO, PZT, GaN, InN, CdS, CdSe, ZnS, CdTe, ZnTe, GaAs, GaSb, InAs, InSb, GaSe, GaP, AlP, quartz crystal, LiTaO3, LiNbO3, La3Ga5SiO14, BaTiO3, PbNb2O6, PBLN, LiGaO3, LiGeO3, TiGeO3, PbTiO3, PbZrO3, PVDF, etc. The piezoelectric layer 12 in the present embodiment may be one of the piezoelectric materials described above, or may be a stack of the above piezoelectric materials. A thickness of the piezoelectric layer 12 is in a range of 10 nm to 100 μm.

In some examples, a material of the first electrode 11 is preferably metal Cu, which has a lattice size is very close to that of the hexagonal phase boron nitride (hBN). Alternatively, the material of the first electrode 11 may be Al, Mo, Co, Ag, Ti, Pt, Ru, W, Au, or an alloy material of any of the above metals. A thickness of the first electrode 11 is in a range of 1 nm to 10 μm.

In some examples, a material of the encapsulation layer 16 is preferably an organic compound capable of blocking moisture and oxygen, such as polyimide, epoxy, or the like. Alternatively, the material of the encapsulation layer 16 may be an inorganic material such as SiNₓ, Al₂O₃, or the like. The encapsulation layer 16 may be a single layer of material or may be a stack of materials.

A method for manufacturing the bulk acoustic wave resonator shown in FIG. 6 is the same as that of the first example, and therefore, a description thereof will not be repeated.

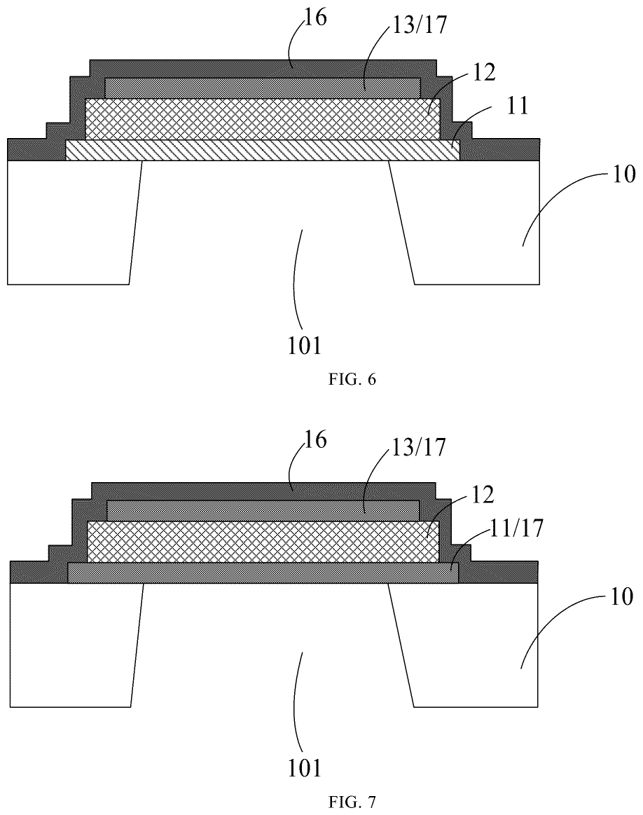

In a third example, FIG. 7 is a schematic diagram of a bulk acoustic wave resonator of a third example of an embodiment of the present disclosure. As shown in FIG. 7, the bulk acoustic wave resonator includes a first base substrate 10, and a first electrode 11, a piezoelectric layer 12, and a second electrode 13 which are sequentially disposed on the first base substrate 10, and the first electrode 11 and the second electrode 13 further serve as functional layers 17. Orthographic projections of any two of the first electrode 11, the piezoelectric layer 12 and the second electrode 13 on the first base substrate 10 at least partially overlap with each other. An encapsulation layer 16 may further be provided on a side of the second electrode 13 away from the first base substrate 10. The first base substrate 10 has a first cavity penetrating through the first base substrate 10 in a thickness direction of the first base substrate 10. The first base substrate 10 includes a first surface (upper surface) and a second surface (lower surface) which are oppositely disposed in the thickness direction of the first base substrate 10, and the first cavity includes a first opening 101 formed in the first surface and a second opening formed in the second surface. The first electrode 11 is disposed on the first surface, and an orthographic projection of the first electrode 11 on a plane of the second surface (a plane where the second surface is located) covers an orthographic projection of the first opening 101 on the plane of the second surface.

In this example, the first electrode 11 and the second electrode 13 further serve as the functional layers 17, that is, each of the first electrode 11 and the second electrode 13 has a function of resisting temperature drift, and the first electrode 11 and the second electrode 13 are respectively arranged on two opposite surfaces of the piezoelectric layer 12, so as to reduce the temperature drift coefficient of the device as much as possible, even to achieve a zero temperature drift coefficient. The bulk acoustic wave resonator having such the structure has a high resonant frequency, a low cost, a small volume, a low insertion loss, a small in-band ripple, a large out-of-band rejection and a good rectangularity. The bulk acoustic wave resonator may be widely applied to various frequency bands greater than 1 GHz in the field of mobile communication, and can effectively filter out low-frequency interference signals and higher harmonics thereof in the ground environment. The signal quality of the mobile communication is improved.

In some examples, the first electrode 11 and the second electrode 13 serve as the functional layers 17, a material of each of the first electrode 11 and the second electrode 13 has a positive temperature coefficient, which changes the temperature drift coefficient of the bulk acoustic wave resonator from −30 ppm/K to be in a range from −10 ppm/K to +10 ppm/K. Further, the material of the second electrode 13 includes, but is not limited to, metal or alloy materials. For example, the material of each of the first electrode 11 and the second electrode 13 is any one of antimony, bismuth, and gallium, or an alloy material of at least two of these. The piezoelectric effect and the inverse piezoelectric effect can be effectively introduced by selecting the proper material of each of the first electrode 11 and the second electrode 13, so that the quality factor of the bulk acoustic wave resonator is improved, and the performance of the device is improved.

In some examples, a material of the first base substrate 10 is preferably glass, and may alternatively be Si, sapphire, SiC, GaAs, GaN, InP, BN, ZnO, etc. A thickness of the first base substrate 10 is in a range of 0.1 μm to 10 mm.

In some examples, a material of the piezoelectric layer 12 is preferably hBN, and may alternatively be cBN, wBN. Alternatively, the material of the piezoelectric layer 12 may be selected from AlN, ZnO, PZT, GaN, InN, CdS, CdSe, ZnS, CdTe, ZnTe, GaAs, GaSb, InAs, InSb, GaSe, GaP, AlP, quartz crystal, LiTaO3, LiNbO3, La3Ga5SiO14, BaTiO3, PbNb2O6, PBLN, LiGaO3, LiGeO3, TiGeO3, PbTiO3, PbZrO3, PVDF, etc. The piezoelectric layer 12 in the present embodiment may be one of the piezoelectric materials described above, or may be a stack of the above piezoelectric materials. A thickness of the piezoelectric layer 12 is in a range of 10 nm to 100 μm.

In some examples, a material of the encapsulation layer 16 is preferably an organic compound capable of blocking moisture and oxygen, such as polyimide, epoxy, or the like. Alternatively, the material of the encapsulation layer 16 may be an inorganic material such as SiNₓ, Al₂O₃, or the like. The encapsulation layer 16 may be a single layer of material or may be a stack of materials.

A method for manufacturing the bulk acoustic wave resonator shown in FIG. 7 is the same as that of the first example, and therefore, a description thereof will not be repeated.

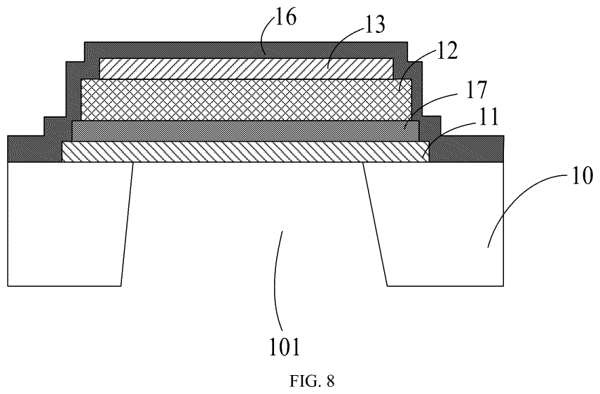

In a fourth example, FIG. 8 is a schematic diagram of a bulk acoustic wave resonator of a fourth example of an embodiment of the present disclosure. As shown in FIG. 8, the bulk acoustic wave resonator includes a first base substrate 10, and a first electrode 11, a functional layer 17, a piezoelectric layer 12, and a second electrode 13 which are sequentially disposed on the first base substrate 10. Orthographic projections of any two of the first electrode 11, the functional layer 17, the piezoelectric layer 12 and the second electrode 13 on the first base substrate 10 at least partially overlap with each other. The functional layer 17 is made of a conductive material and can suppress the temperature drift. An encapsulation layer 16 may further be provided on a side of the second electrode 13 away from the first base substrate 10. The first base substrate 10 has a first cavity penetrating through the first base substrate 10 in a thickness direction of the first base substrate 10. The first base substrate 10 includes a first surface (upper surface) and a second surface (lower surface) which are oppositely disposed in the thickness direction of the first base substrate 10, and the first cavity includes a first opening 101 formed in the first surface and a second opening formed in the second surface. The first electrode 11 is disposed on the first surface, and an orthographic projection of the first electrode 11 on a plane of the second surface (a plane where the second surface is located) covers an orthographic projection of the first opening 101 on the plane of the second surface.

In this example, the functional layer 17 is disposed between the first electrode 11 and the piezoelectric layer 12, is capable of suppressing the temperature drift and is in contact with the piezoelectric layer 12. With such the arrangement, the temperature drift coefficient of the device can be reduced as much as possible, even a zero temperature drift coefficient can be achieved. The bulk acoustic wave resonator having such the structure has a high resonant frequency, a low cost, a small volume, a low insertion loss, a small in-band ripple, a large out-of-band rejection and a good rectangularity. The bulk acoustic wave resonator may be widely applied to various frequency bands greater than 1 GHz in the field of mobile communication, and can effectively filter out low-frequency interference signals and higher harmonics thereof in the ground environment. The signal quality of the mobile communication is improved.

In some examples, a material of the functional layer 17 has a positive temperature coefficient, which changes the temperature drift coefficient of the bulk acoustic wave resonator from −30 ppm/K to be in a range from −10 ppm/K to +10 ppm/K. Further, the material of the second electrode 13 includes, but is not limited to, metal or alloy materials. For example, the material of each of the first electrode 11 and the second electrode 13 is any one of antimony, bismuth, and gallium, or an alloy material of at least two of these. The piezoelectric effect and the inverse piezoelectric effect can be effectively introduced by selecting the proper material of each of the first electrode 11 and the second electrode 13, so that the quality factor of the bulk acoustic wave resonator is improved, and the performance of the device is improved.

In some examples, a material of the first base substrate 10 is preferably glass, and may alternatively be Si, sapphire, SiC, GaAs, GaN, InP, BN, ZnO, etc. A thickness of the first base substrate 10 is in a range of 0.1 μm to 10 mm.

In some examples, a material of the piezoelectric layer 12 is preferably hBN, and may alternatively be cBN, wBN. Alternatively, the material of the piezoelectric layer 12 may be selected from AlN, ZnO, PZT, GaN, InN, CdS, CdSe, ZnS, CdTe, ZnTe, GaAs, GaSb, InAs, InSb, GaSe, GaP, AlP, quartz crystal, LiTaO3, LiNbO3, La3Ga5SiO14, BaTiO3, PbNb2O6, PBLN, LiGaO3, LiGeO3, TiGeO3, PbTiO3, PbZrO3, PVDF, etc. The piezoelectric layer 12 in the present embodiment may be one of the piezoelectric materials described above, or may be a stack of the above piezoelectric materials. A thickness of the piezoelectric layer 12 is in a range of 10 nm to 100 μm.

In some examples, a material of the first electrode 11 is preferably metal Cu, which has a lattice size is very close to that of the hexagonal phase boron nitride (hBN). Alternatively, the material of the first electrode 11 may be Al, Mo, Co, Ag, Ti, Pt, Ru, W, Au, or an alloy material of any of the above metals. A thickness of the first electrode 11 is in a range of 1 nm to 10 μm.

In some examples, a material of the second electrode 13 may be selected from Cu, Al, Mo, Co, Ag, Ti, Pt, Ru, W, Au, or an alloy material of any of the above metals. A thickness of the second electrode 13 is in a range of 1 nm to 10 μm.

In some examples, a material of the encapsulation layer 16 is preferably an organic compound capable of blocking moisture and oxygen, such as polyimide, epoxy, or the like. Alternatively, the material of the encapsulation layer 16 may be an inorganic material such as SiNₓ, Al₂O₃, or the like. The encapsulation layer 16 may be a single layer of material or may be a stack of materials.

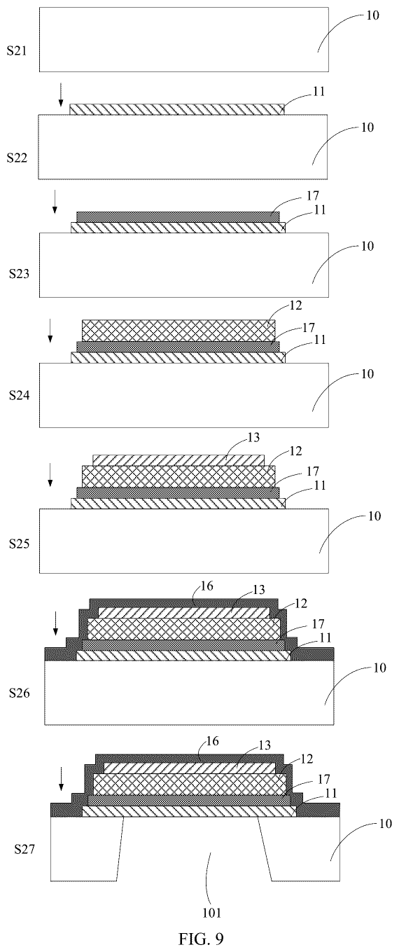

For the bulk acoustic wave resonator shown in FIG. 8, an embodiment of the present disclosure provides a method for manufacturing a bulk acoustic wave resonator. FIG. 9 is a flow chart of manufacturing a bulk acoustic wave resonator shown in FIG. 8. As shown in FIG. 9, the manufacturing method may specifically include the following steps S21 to S27.

At the step S21, a first base substrate 10 is provided.

In this step, the first base substrate 10 may be cleaned and then dried by air knife.

At the step S22, a first electrode 11 is formed on the first base substrate 10.

In some examples, the step S22 may include depositing a first conductive film on the first base substrate 10, preferably by direct current magnetron sputtering (alternatively, radio frequency magnetron sputtering), alternatively by pulsed laser sputtering (PLD), molecular beam epitaxy (MBE), thermal evaporation, electron beam evaporation, or by attaching a copper foil. Processes including coating glue (or spraying glue), pre-baking, exposing, developing and post-baking are performed on the first conductive film. Finally, an etching process is performed, preferably a wet etching process, or alternatively a dry etching process, to form a pattern including the first electrode 11.

At the step S23, a functional layer 17 is formed on the first base substrate 10 after the above steps.

In some examples, the step S23 may include depositing a third conductive film on the first base substrate 10, preferably by direct current magnetron sputtering (alternatively, radio frequency magnetron sputtering), alternatively by pulsed laser sputtering (PLD), molecular beam epitaxy (MBE), thermal evaporation, electron beam evaporation. Processes including coating glue (or spraying glue), pre-baking, exposing, developing and post-baking are performed on the first conductive film. Finally, an etching process is performed, preferably a wet etching process, or alternatively a dry etching process, to form a pattern including the first electrode 11.

At the step S24, a piezoelectric layer 12 is formed on the first base substrate 10 after the above steps.

In some examples, as an example, a material of the piezoelectric layer 12 is hBN, in step S24, an orientation growth of the piezoelectric material may be performed firstly, preferably by radio frequency magnetron sputtering, and a target material is hBN. A hBN oriented film rich in nitrogen vacancies (whose the piezoelectric property is much better than that of BN without nitrogen vacancies) is formed by controlling an air pressure and a temperature of Ar and N2 and a time and temperature of post-annealing in the deposition, and preferably the growth orientation is (100), and may alternatively be (001) and (111). The film deposition method may be selected from pulsed laser sputtering (PLD), molecular beam epitaxy (MBE), metal organic chemical vapor deposition (MOCVD), plasma enhanced chemical vapor deposition (PECVD), and the like. The piezoelectric layer 12 is subjected to a photolithography process including coating glue (or spraying glue), pre-baking, exposing, developing and post-baking. Finally, the piezoelectric material layer is etched to form a pattern of the piezoelectric material layer 12; a preferred etching process may be a wet etching process or a dry etching process.

At the step S25, a second electrode 13 is formed on the first base substrate 10 after the above steps.

In some examples, step S25 may include depositing a second conductive film, preferably by direct current magnetron sputtering (alternatively by radio frequency magnetron sputtering), alternatively by pulsed laser sputtering (PLD), molecular beam epitaxy (MBE), thermal evaporation, electron beam evaporation. Processes including coating glue (or spraying glue), pre-baking, exposing, developing and post-baking are performed on the second conductive film. Finally, an etching process is performed, preferably a wet etching process, or alternatively a dry etching process, to form the second electrode 13. The second conductive film formed on a hole wall is thinner, which is not favorable for low-loss transmission of radio frequency signals, so that the second conductive film in the first connecting via 121 may be thickened by an electroplating process, and then a pattern of the second electrode 13 is formed.

At the step S26, an encapsulation layer 16 is formed on the first base substrate 10 after the above steps.

In some examples, a material of the encapsulation layer 16 may be an organic material polyimide. In this case, step S26 may include performing liquid coating of the organic material, such as spin coating, spraying, ink-jet printing, or transferring or the like, and then performing a heat curing process to form a pattern of the encapsulation layer 16.

At the step S27, the first base substrate 10 is turned over to form a first cavity 101 after the above steps.

In some examples, the first base substrate 10 may be a glass substrate, in which case, the step S27 may include forming the first cavity 101 penetrating through the first base substrate 10 in a thickness direction of the first base substrate 10 by bombarding the first base substrate 10 using a laser-induced method and then HF etching. The first cavity 101 has a cross-section which is substantially perpendicular to the glass surface at an angle of approximately 90°. The first cavity 101 may be formed by wet etching or dry etching for other non-glass substrates.

In a fifth example: FIG. 10 is a schematic diagram of a bulk acoustic wave resonator of a fifth example of an embodiment of the present disclosure. As shown in FIG. 10, the bulk acoustic wave resonator includes a first base substrate 10, and a functional layer 17, a first electrode 11, a piezoelectric layer 12, and a second electrode 13 which are sequentially disposed on the first base substrate 10. Orthographic projections of any two of the functional layer 17, the first electrode 11, the piezoelectric layer 12 and the second electrode 13 on the first base substrate 10 at least partially overlap with each other. The functional layer 17 is made of a conductive material and can suppress the temperature drift. An encapsulation layer 16 may further be provided on a side of the second electrode 13 away from the first base substrate 10. The first base substrate 10 has a first cavity penetrating through the first base substrate 10 in a thickness direction of the first base substrate 10. The first base substrate 10 includes a first surface (upper surface) and a second surface (lower surface) which are oppositely disposed in the thickness direction of the first base substrate 10, and the first cavity includes a first opening 101 formed in the first surface and a second opening formed in the second surface. The functional layer 17 is disposed on the first surface, and an orthographic projection of the functional layer 17 on a plane of the second surface (a plane where the second surface is located) covers an orthographic projection of the first opening 101 on the plane of the second surface.

As can be seen from FIG. 10, the bulk acoustic wave resonator in the fifth example is different from the bulk acoustic wave resonator in the fourth example only in that the first electrode 11 is closer to the piezoelectric layer 12 than the functional layer 17, that is, the functional layer 17 and the piezoelectric layer 12 are separated from each other by the first electrode 11, and the functional layer 17 is not in direct contact with the piezoelectric layer 12. Compared with the fourth example, in this fifth example, a high resistance cannot be introduced while the temperature drift coefficient of the device can be reduced. The bulk acoustic wave resonator having such the structure has a high resonant frequency, a low cost, a small volume, a low insertion loss, a small in-band ripple, a large out-of-band rejection and a good rectangularity. The bulk acoustic wave resonator may be widely applied to various frequency bands greater than 1 GHz in the field of mobile communication, and can effectively filter out low-frequency interference signals and higher harmonics thereof in the ground environment. The signal quality of the mobile communication is improved.

The materials of the layers in the bulk acoustic wave resonator in the fifth example may be the same as those in the fourth example, and thus the description thereof will not be repeated. In addition, the method for manufacturing a bulk acoustic wave resonator in the fifth example is substantially the same as that in the fourth example, except that in the fifth example, the functional layer 17 is formed firstly, and then the first electrode 11 is formed, and the remaining steps may be the same as those in the fourth example, and thus are not repeated herein.

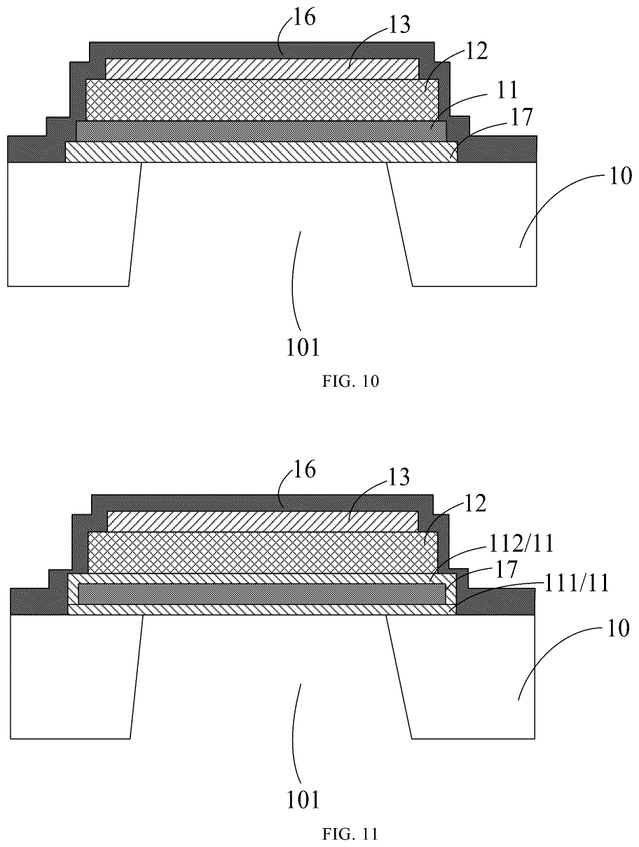

In a sixth example: FIG. 11 is a schematic diagram of a bulk acoustic wave resonator of a sixth example of an embodiment of the present disclosure. As shown in FIG. 11, the bulk acoustic wave resonator includes a first base substrate 10, and a first electrode 11, a piezoelectric layer 12, and a second electrode 13 which are sequentially disposed on the first base substrate 10, and the first electrode 11 includes a first sub-electrode 111 and a second sub-electrode 112 in a direction away from the first base substrate 10. The bulk acoustic wave resonator further includes a functional layer 17 located between the first sub-electrode 111 and the second sub-electrode 112. Orthographic projections of any two of the first sub-electrode 111, the functional layer 17, the second sub-electrode 112, the piezoelectric layer 12 and the second electrode 13 on the first base substrate 10 at least partially overlap with each other. The functional layer 17 is made of a conductive material and can suppress the temperature drift. An encapsulation layer 16 may further be provided on a side of the second electrode 13 away from the first base substrate 10. The first base substrate 10 has a first cavity penetrating through the first base substrate 10 in a thickness direction of the first base substrate 10. The first base substrate 10 includes a first surface (upper surface) and a second surface (lower surface) which are oppositely disposed in the thickness direction of the first base substrate 10, and the first cavity includes a first opening 101 formed in the first surface and a second opening formed in the second surface. The first electrode 11 is disposed on the first surface, and an orthographic projection of the first electrode 11 on a plane of the second surface (a plane where the second surface is located) covers an orthographic projection of the first opening 101 on the plane of the second surface.

In this example, the first electrode 11 includes the first sub-electrode 111 and the second sub-electrode 112, and the functional layer 17 is disposed between the first sub-electrode 111 and the second sub-electrode 112, that is, the functional layer 17 is disposed in the first electrode 11. At this time, the functional layer 17 is not in direct contact with the piezoelectric layer 12. Compared with the fourth example, in this example, a high resistance cannot be introduced while the temperature drift coefficient of the device can be reduced. The bulk acoustic wave resonator having such the structure has a high resonant frequency, a low cost, a small volume, a low insertion loss, a small in-band ripple, a large out-of-band rejection and a good rectangularity. The bulk acoustic wave resonator may be widely applied to various frequency bands greater than 1 GHz in the field of mobile communication, and can effectively filter out low-frequency interference signals and higher harmonics thereof in the ground environment. The signal quality of the mobile communication is improved.

In some examples, materials of the first sub-electrode 111 and the second sub-electrode 112 may be the same, and each may be preferably Cu, Al, Mo, Co, Ag, Ti, Pt, Ru, W, Au, or an alloy material formed of the above metals.

The materials of the first base substrate 10, the functional layer 17, the piezoelectric layer 12 and the second electrode 13 of the bulk acoustic wave resonator in the sixth example may be the same as those in the fourth example, and therefore, the description thereof is not repeated here.

The method for manufacturing a bulk acoustic wave resonator in the sixth example is substantially the same as that in the fourth example, except that for steps of forming the first electrode 11 and the functional layer 17. In this example, the steps of forming the first electrode 11 and the functional layer 17 may include: sequentially forming the first sub-electrode 111, the functional layer 17, and the second sub-electrode 112 on the first base substrate 10. At this time, the first sub-electrode 111 and the second sub-electrode 112 form the first electrode 11.

In some examples, the process of forming the first sub-electrode 111 may be the same as the process of forming the second sub-electrode 112. For example: the step of forming the first sub-electrode 111 may include depositing a first conductive film on the first base substrate 10, preferably by direct current magnetron sputtering (alternatively, radio frequency magnetron sputtering), alternatively by pulsed laser sputtering (PLD), molecular beam epitaxy (MBE), thermal evaporation, electron beam evaporation, or by attaching a copper foil. Processes including coating glue (or spraying glue), pre-baking, exposing, developing and post-baking are performed on the first conductive film. Finally, an etching process is performed, preferably a wet etching process, or alternatively a dry etching process, to form a pattern including the first sub-electrode 111. The second sub-electrode 112 may be formed on the first base substrate 10 on which the functional layer 17 is formed, and the process for forming the second sub-electrode 112 is the same as the process for forming the first sub-electrode 111, and the description thereof is not repeated.

The remaining steps of the method for manufacturing a bulk acoustic wave resonator in the sixth example may be the same as those in the fourth example, and thus, the description thereof is not repeated.

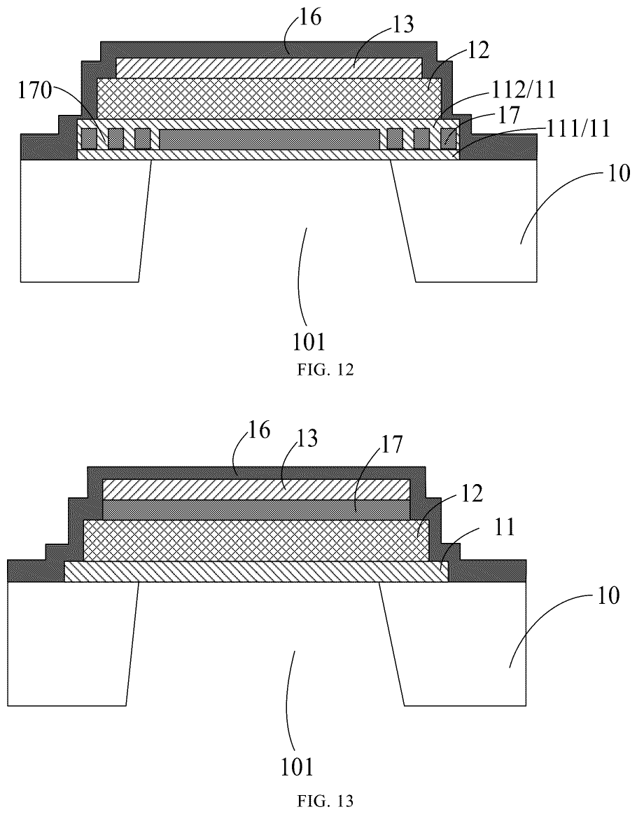

In a seventh example: FIG. 12 is a schematic diagram of a bulk acoustic wave resonator of a seventh example of an embodiment of the present disclosure. As shown in FIG. 12, the structure of the bulk acoustic wave resonator is substantially the same as that in the sixth example, except that the functional layer 17 in the seventh example has a hollowed-out pattern.

The functional layer 17 of the bulk acoustic wave resonator has the hollowed-out pattern, so that the transmission of the microwave signal cannot be influenced by the provided functional layer 17 in the bulk acoustic wave resonator. The rest of the structure in the seventh example is the same as that in the sixth example, and therefore, the description thereof is not repeated.

In some examples, referring to FIG. 12, the hollowed-out pattern of the functional layer 17 does not overlap with an orthographic projection of the first opening 101 in the first base substrate 10 on the first sub-electrode 111. With such the arrangement, the piezoelectric characteristics of the piezoelectric material with a voltage applied to the first electrode 11 and the second electrode 13 can be ensured.

The method for manufacturing a bulk acoustic wave resonator in the seventh example is substantially the same as that in the sixth example, except that the functional layer 17 is formed to have the hollowed-out pattern after a third conductive film is patterned. The remaining steps may be the same as those in the sixth example, and thus, the description thereof is not repeated.

In an eighth example: FIG. 13 is a schematic diagram of a bulk acoustic wave resonator of an eight example of an embodiment of the present disclosure. As shown in FIG. 13, the bulk acoustic wave resonator includes a first base substrate 10, and a first electrode 11, a piezoelectric layer 12, a functional layer 17 and a second electrode 13 which are sequentially disposed on the first base substrate 10. Orthographic projections of any two of the first electrode 11, the piezoelectric layer 12, the functional layer 17 and the second electrode 13 on the first base substrate 10 at least partially overlap with each other. The functional layer 17 is made of a conductive material and can suppress the temperature drift. An encapsulation layer 16 may further be provided on a side of the second electrode 13 away from the first base substrate 10. The first base substrate 10 has a first cavity penetrating through the first base substrate 10 in a thickness direction of the first base substrate 10. The first base substrate 10 includes a first surface (upper surface) and a second surface (lower surface) which are oppositely disposed in the thickness direction of the first base substrate 10, and the first cavity includes a first opening 101 formed in the first surface and a second opening formed in the second surface. The first electrode 11 is disposed on the first surface, and an orthographic projection of the first electrode 11 on a plane of the second surface (a plane where the second surface is located) covers an orthographic projection of the first opening 101 on the plane of the second surface.

In this example, the functional layer 17 is disposed between the second electrode 13 and the piezoelectric layer 12, is capable of suppressing the temperature drift and is in contact with the piezoelectric layer 12. With such the arrangement, the temperature drift coefficient of the device can be reduced as much as possible, even a zero temperature drift coefficient can be achieved. The bulk acoustic wave resonator having such the structure has a high resonant frequency, a low cost, a small volume, a low insertion loss, a small in-band ripple, a large out-of-band rejection and a good rectangularity. The bulk acoustic wave resonator may be widely applied to various frequency bands greater than 1 GHz in the field of mobile communication, and can effectively filter out low-frequency interference signals and higher harmonics thereof in the ground environment. The signal quality of the mobile communication is improved.

In some examples, a material of the functional layer 17 has a positive temperature coefficient, which changes the temperature drift coefficient of the bulk acoustic wave resonator from −30 ppm/K to be in a range from −10 ppm/K to +10 ppm/K. Further, the material of the second electrode 13 includes, but is not limited to, metal or alloy materials. For example, the material of each of the first electrode 11 and the second electrode 13 is any one of antimony, bismuth, and gallium, or an alloy material of at least two of these. The piezoelectric effect and the inverse piezoelectric effect can be effectively introduced by selecting the proper material of each of the first electrode 11 and the second electrode 13, so that the quality factor of the bulk acoustic wave resonator is improved, and the performance of the device is improved.

In some examples, a material of the first base substrate 10 is preferably glass, and may alternatively be Si, sapphire, SiC, GaAs, GaN, InP, BN, ZnO, etc. A thickness of the first base substrate 10 is in a range of 0.1 μm to 10 mm.

In some examples, a material of the piezoelectric layer 12 is preferably hBN, and may alternatively be cBN, wBN. Alternatively, the material of the piezoelectric layer 12 may be selected from AlN, ZnO, PZT, GaN, InN, CdS, CdSe, ZnS, CdTe, ZnTe, GaAs, GaSb, InAs, InSb, GaSe, GaP, AlP, quartz crystal, LiTaO3, LiNbO3, La3Ga5SiO14, BaTiO3, PbNb2O6, PBLN, LiGaO3, LiGeO3, TiGeO3, PbTiO3, PbZrO3, PVDF, etc. The piezoelectric layer 12 in the present embodiment may be one of the piezoelectric materials described above, or may be a stack of the above piezoelectric materials. A thickness of the piezoelectric layer 12 is in a range of 10 nm to 100 μm.

In some examples, a material of the first electrode 11 is preferably metal Cu, which has a lattice size is very close to that of the hexagonal phase boron nitride (hBN). Alternatively, the material of the first electrode 11 may be Al, Mo, Co, Ag, Ti, Pt, Ru, W, Au, or an alloy material of any of the above metals. A thickness of the first electrode 11 is in a range of 1 nm to 10 μm.

In some examples, a material of the second electrode 13 may be selected from Cu, Al, Mo, Co, Ag, Ti, Pt, Ru, W, Au, or an alloy material of any of the above metals. A thickness of the second electrode 13 is in a range of 1 nm to 10 μm.

In some examples, a material of the encapsulation layer 16 is preferably an organic compound capable of blocking moisture and oxygen, such as polyimide, epoxy, or the like. Alternatively, the material of the encapsulation layer 16 may be an inorganic material such as SiNₓ, Al₂O₃, or the like. The encapsulation layer 16 may be a single layer of material or may be a stack of materials.

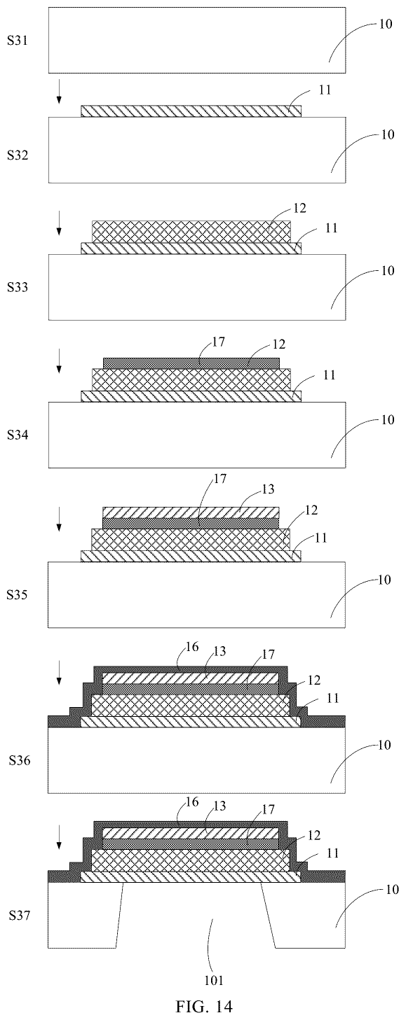

For the bulk acoustic wave resonator shown in FIG. 13, an embodiment of the present disclosure provides a method for manufacturing a bulk acoustic wave resonator. FIG. 14 is a flowchart for manufacturing the bulk acoustic wave resonator shown in FIG. 13. As shown in FIG. 14, the method may specifically include the following steps S31 to S37.

At the step S31, a first base substrate 10 is provided.

In this step, the first base substrate 10 may be cleaned and then dried by air knife.

At the step S32, a first electrode 11 is formed on the first base substrate 10.

In some examples, the step S32 may include depositing a first conductive film on the first base substrate 10, preferably by direct current magnetron sputtering (alternatively, radio frequency magnetron sputtering), alternatively by pulsed laser sputtering (PLD), molecular beam epitaxy (MBE), thermal evaporation, electron beam evaporation, or by attaching a copper foil. Processes including coating glue (or spraying glue), pre-baking, exposing, developing and post-baking are performed on the first conductive film. Finally, an etching process is performed, preferably a wet etching process, or alternatively a dry etching process, to form a pattern including the first electrode 11.

At the step S33, a piezoelectric layer 12 is formed on the first base substrate 10 after the above steps.

In some examples, as an example, a material of the piezoelectric layer 12 is hBN, in step S33, an orientation growth of the piezoelectric material may be performed firstly, preferably by radio frequency magnetron sputtering, and a target material is hBN. A hBN oriented film rich in nitrogen vacancies (whose the piezoelectric property is much better than that of BN without nitrogen vacancies) is formed by controlling an air pressure and a temperature of Ar and N2 and a time and temperature of post-annealing in the deposition, and preferably the growth orientation is (100), and may alternatively be (001) and (111). The film deposition method may be selected from pulsed laser sputtering (PLD), molecular beam epitaxy (MBE), metal organic chemical vapor deposition (MOCVD), plasma enhanced chemical vapor deposition (PECVD), and the like. The piezoelectric layer 12 is subjected to a photolithography process including coating glue (or spraying glue), pre-baking, exposing, developing and post-baking. Finally, the piezoelectric material layer is etched to form a pattern of the piezoelectric layer 12; a preferred etching process may be a wet etching process or a dry etching process.

At the step S34, a functional layer 17 is formed on the first base substrate 10 after the above steps.

In some examples, the step S34 may include depositing a third conductive film on the first base substrate 10, preferably by direct current magnetron sputtering (alternatively, radio frequency magnetron sputtering), alternatively by pulsed laser sputtering (PLD), molecular beam epitaxy (MBE), thermal evaporation, electron beam evaporation. Processes including coating glue (or spraying glue), pre-baking, exposing, developing and post-baking are performed on the first conductive film. Finally, an etching process is performed, preferably a wet etching process, or alternatively a dry etching process, to form a pattern including the first electrode 11.

At the step S35, a second electrode 13 is formed on the first base substrate 10 after the above steps.

In some examples, step S35 may include depositing a second conductive film, preferably by direct current magnetron sputtering (alternatively, radio frequency magnetron sputtering), alternatively by pulsed laser sputtering (PLD), molecular beam epitaxy (MBE), thermal evaporation, electron beam evaporation. Processes including coating glue (or spraying glue), pre-baking, exposing, developing and post-baking are performed on the second conductive film. Finally, an etching process is performed, preferably a wet etching process, or alternatively a dry etching process, to form the second electrode 13. The second conductive film formed on a hole wall is thinner, which is not favorable for low-loss transmission of radio frequency signals, so that the second conductive film in the first connecting via 121 may be thickened by an electroplating process, and then a pattern of the second electrode 13 is formed.

At the step S36, an encapsulation layer 16 is formed on the first base substrate 10 after the above steps.

In some examples, a material of the encapsulation layer 16 may be an organic material polyimide. In this case, step S36 may include performing liquid coating of the organic material, such as spin coating, spraying, ink-jet printing, or transferring or the like, and then performing a heat curing process to form a pattern of the encapsulation layer 16.

At the step S37, the first base substrate 10 is turned over to form a first cavity 101 after the above steps.

In some examples, the first base substrate 10 may be a glass substrate, in which case, the step S37 may include forming the first cavity 101 penetrating through the first base substrate 10 in a thickness direction of the first base substrate 10 by bombarding the first base substrate 10 using a laser-induced method and then HF etching. The first cavity 101 has a cross-section which is substantially perpendicular to the glass surface at an angle of approximately 90°. The first cavity 101 may be formed by wet etching or dry etching for other non-glass substrates.

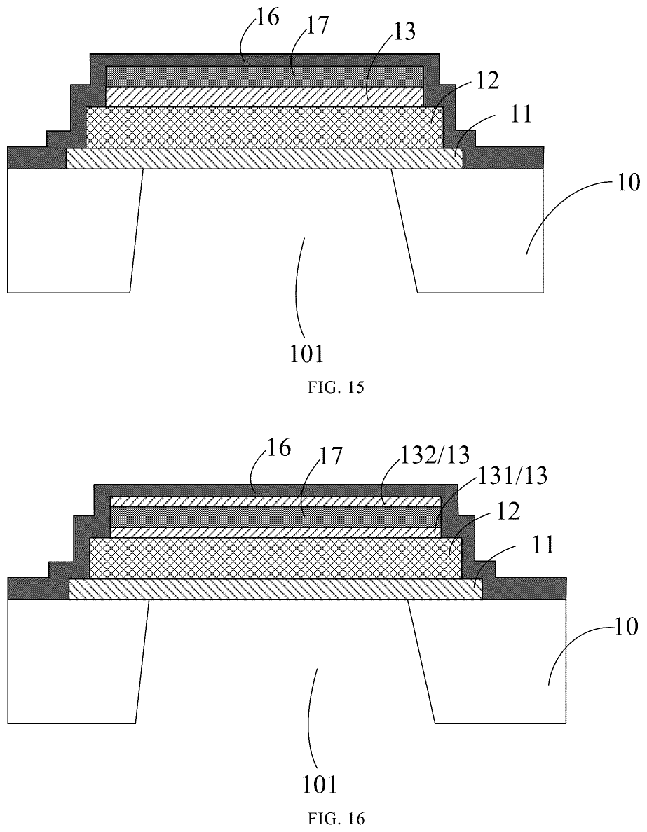

In a ninth example: FIG. 15 is a schematic diagram of a bulk acoustic wave resonator of a ninth example of an embodiment of the present disclosure. As shown in FIG. 15, the bulk acoustic wave resonator includes a first base substrate 10, and a first electrode 11, a piezoelectric layer 12, a second electrode 13 and a functional layer 17 which are sequentially disposed on the first base substrate 10. Orthographic projections of any two of the first electrode 11, the piezoelectric layer 12, the second electrode 13 and the functional layer 17 on the first base substrate 10 at least partially overlap with each other. The functional layer 17 is made of a conductive material and can suppress the temperature drift. An encapsulation layer 16 may further be provided on a side of the second electrode 13 away from the first base substrate 10. The first base substrate 10 has a first cavity penetrating through the first base substrate 10 in a thickness direction of the first base substrate 10. The first base substrate 10 includes a first surface (upper surface) and a second surface (lower surface) which are oppositely disposed in the thickness direction of the first base substrate 10, and the first cavity includes a first opening 101 formed in the first surface and a second opening formed in the second surface. The functional layer 17 is disposed on the first surface, and an orthographic projection of the functional layer 17 on a plane of the second surface (a plane where the second surface is located) covers an orthographic projection of the first opening 101 on the plane of the second surface.

As can be seen from FIG. 15, the bulk acoustic wave resonator in the ninth example is different from the bulk acoustic wave resonator in the eight example only in that the second electrode 13 is closer to the piezoelectric layer 12 than the functional layer 17, that is, the functional layer 17 and the piezoelectric layer 12 are separated from each other by the second electrode 13, and the functional layer 17 is not in direct contact with the piezoelectric layer 12. Compared with the eight example, in this ninth example, a high resistance cannot be introduced while the temperature drift coefficient of the device can be reduced. The bulk acoustic wave resonator having such the structure has a high resonant frequency, a low cost, a small volume, a low insertion loss, a small in-band ripple, a large out-of-band rejection and a good rectangularity. The bulk acoustic wave resonator may be widely applied to various frequency bands greater than 1 GHz in the field of mobile communication, and can effectively filter out low-frequency interference signals and higher harmonics thereof in the ground environment. The signal quality of the mobile communication is improved.

The materials of the layers in the bulk acoustic wave resonator in the ninth example may be the same as those in the eight example, and thus the description thereof will not be repeated. In addition, the method for manufacturing a bulk acoustic wave resonator in the ninth example is substantially the same as that in the eight example, except that in the ninth example, the second electrode 13 is formed firstly, and then the functional layer 17 is formed, and the remaining steps may be the same as those in the eight example, and thus are not repeated herein.

In a tenth example: FIG. 16 is a schematic diagram of a bulk acoustic wave resonator of a tenth example of an embodiment of the present disclosure. As shown in FIG. 16, the bulk acoustic wave resonator includes a first base substrate 10, and a first electrode 11, a piezoelectric layer 12, and a second electrode 13 which are sequentially disposed on the first base substrate. The second electrode 13 includes a third sub-electrode 131 and a fourth sub-electrode 132 in a direction away from the first base substrate 10. The bulk acoustic wave resonator further includes a functional layer 17 located between the third sub-electrode 131 and the fourth sub-electrode 132. Orthographic projections of any two of the first electrode 11, the piezoelectric layer 12, the third sub-electrode 131, the functional layer 17 and the fourth sub-electrode 132 on the first base substrate 10 at least partially overlap with each other. The functional layer 17 is made of a conductive material and can suppress the temperature drift. An encapsulation layer 16 may further be provided on a side of the fourth sub-electrode 132 away from the first base substrate 10. The first base substrate 10 has a first cavity penetrating through the first base substrate 10 in a thickness direction of the first base substrate 10. The first base substrate 10 includes a first surface (upper surface) and a second surface (lower surface) which are oppositely disposed in the thickness direction of the first base substrate 10, and the first cavity includes a first opening 101 formed in the first surface and a second opening formed in the second surface. The first electrode 11 is disposed on the first surface, and an orthographic projection of the first electrode 11 on a plane of the second surface (a plane where the second surface is located) covers an orthographic projection of the first opening 101 on the plane of the second surface.

In this example, the second electrode 13 includes the third sub-electrode 131 and the fourth sub-electrode 132, and the functional layer 17 is disposed between the third sub-electrode 131 and the fourth sub-electrode 132, that is, the functional layer 17 is disposed in the second electrode 13. At this time, the functional layer 17 is not in direct contact with the piezoelectric layer 12. Compared with the eighth example, in this example, a high resistance cannot be introduced while the temperature drift coefficient of the device can be reduced. The bulk acoustic wave resonator having such the structure has a high resonant frequency, a low cost, a small volume, a low insertion loss, a small in-band ripple, a large out-of-band rejection and a good rectangularity. The bulk acoustic wave resonator may be widely applied to various frequency bands greater than 1 GHz in the field of mobile communication, and can effectively filter out low-frequency interference signals and higher harmonics thereof in the ground environment. The signal quality of the mobile communication is improved.

In some examples, materials of the third sub-electrode 131 and the fourth sub-electrode 132 may be the same, and each may be preferably Cu, Al, Mo, Co, Ag, Ti, Pt, Ru, W, Au, or an alloy material formed of the above metals.

The materials of the first base substrate 10, the functional layer 17, the piezoelectric layer 12 and the second electrode 13 of the bulk acoustic wave resonator in the tenth example may be the same as those in the fourth example, and therefore, the description thereof is not repeated here.

The method for manufacturing a bulk acoustic wave resonator in the tenth example is substantially the same as that in the eighth example, except that for steps of forming the second electrode 13 and the functional layer 17. In this example, the steps of forming the second electrode 13 and the functional layer 17 may include: sequentially forming the third sub-electrode 131, the functional layer 17, and the fourth sub-electrode 132 on the first base substrate 10. At this time, the third sub-electrode 131 and the fourth sub-electrode 132 form the second electrode 13.

In some examples, the process of forming the third sub-electrode 131 may be the same as the process of forming the fourth sub-electrode 132. For example: the step of forming the third sub-electrode 131 may include depositing a second conductive film on the first base substrate 10 on which the piezoelectric layer 12 is formed, preferably by direct current magnetron sputtering (alternatively, radio frequency magnetron sputtering), alternatively by pulsed laser sputtering (PLD), molecular beam epitaxy (MBE), thermal evaporation, electron beam evaporation, or by attaching a copper foil. Processes including coating glue (or spraying glue), pre-baking, exposing, developing and post-baking are performed on the first conductive film. Finally, an etching process is performed, preferably a wet etching process, or alternatively a dry etching process, to form a pattern including the third sub-electrode 131. The fourth sub-electrode 132 may be formed on the first base substrate 10 on which the functional layer 17 is formed, and the process for forming the fourth sub-electrode 132 is the same as the process for forming the third sub-electrode 131, and the description thereof is not repeated.

The remaining steps of the method for manufacturing a bulk acoustic wave resonator in the tenth example may be the same as those in the eighth example, and thus, the description thereof is not repeated.

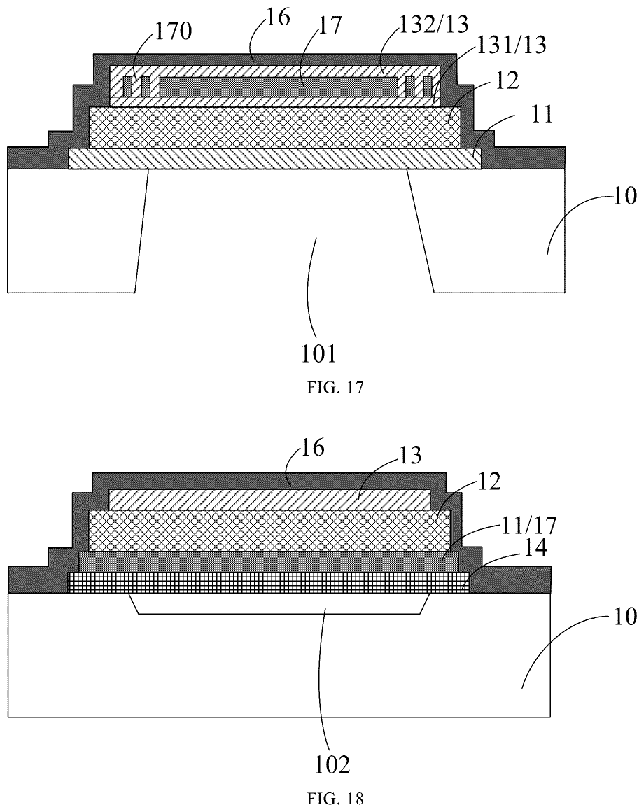

In an eleventh example: FIG. 17 is a schematic diagram of a bulk acoustic wave resonator of an eleventh example of an embodiment of the present disclosure. As shown in FIG. 17, the structure of the bulk acoustic wave resonator is substantially the same as that in the tenth example, except that the functional layer 17 in the eleventh example has a hollowed-out pattern.

The functional layer 17 of the bulk acoustic wave resonator has the hollowed-out pattern, so that the transmission of the microwave signal cannot be influenced by the provided functional layer 17 in the bulk acoustic wave resonator. The rest of the structure in the eleventh example is the same as that in the tenth example, and therefore, the description thereof is not repeated.

In some examples, referring to FIG. 17, the hollowed-out pattern of the functional layer 17 does not overlap with an orthographic projection of the first opening 101 in the first base substrate 10 on the third sub-electrode 131. With such the arrangement, the piezoelectric characteristics of the piezoelectric material with a voltage applied to the first electrode 11 and the second electrode 13 can be ensured.

The method for manufacturing a bulk acoustic wave resonator in the eleventh example is substantially the same as that in the tenth example, except that the functional layer 17 is formed to have the hollowed-out pattern after a third conductive film is patterned. The remaining steps may be the same as those in the tenth example, and thus, the description thereof is not repeated.

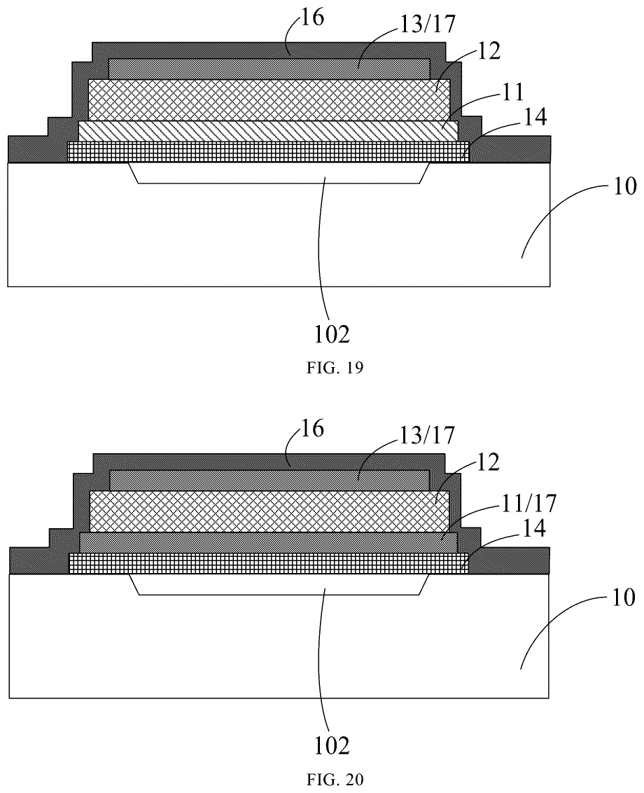

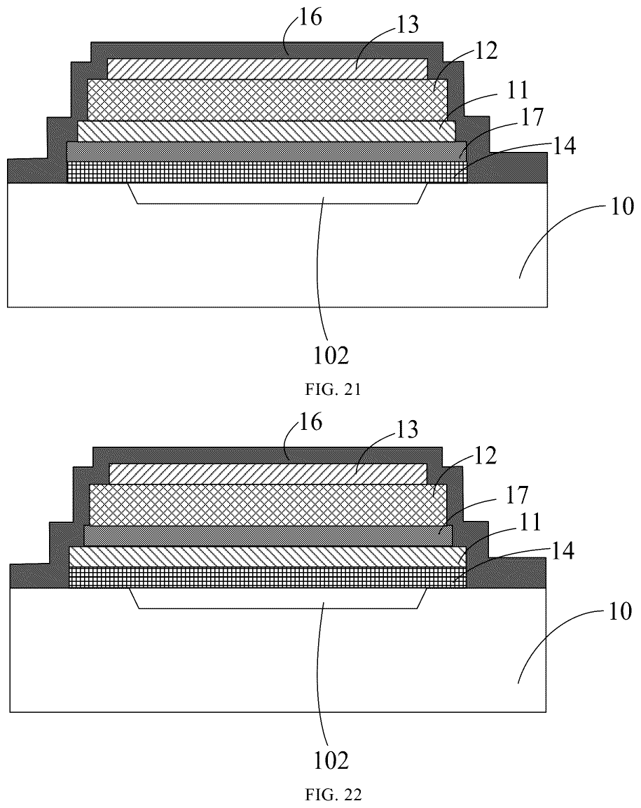

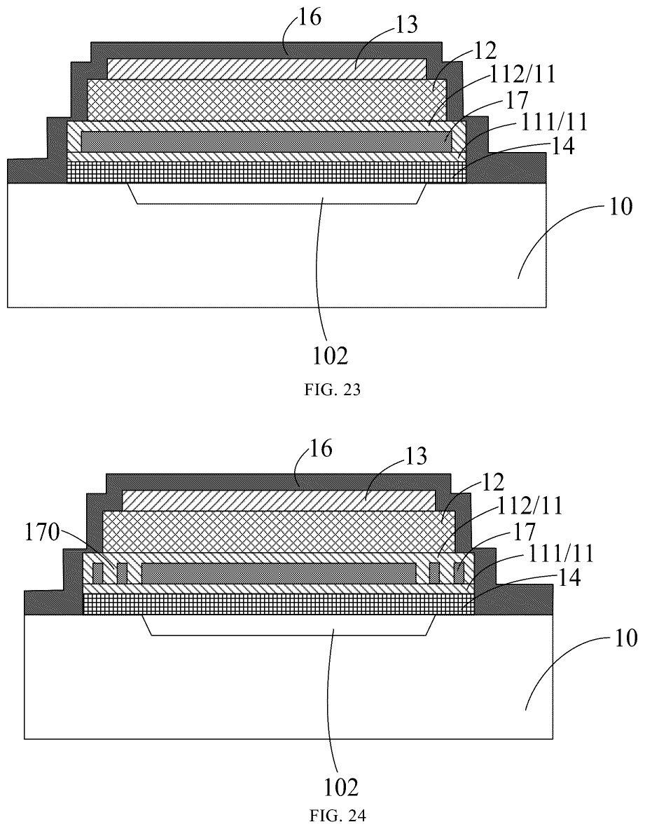

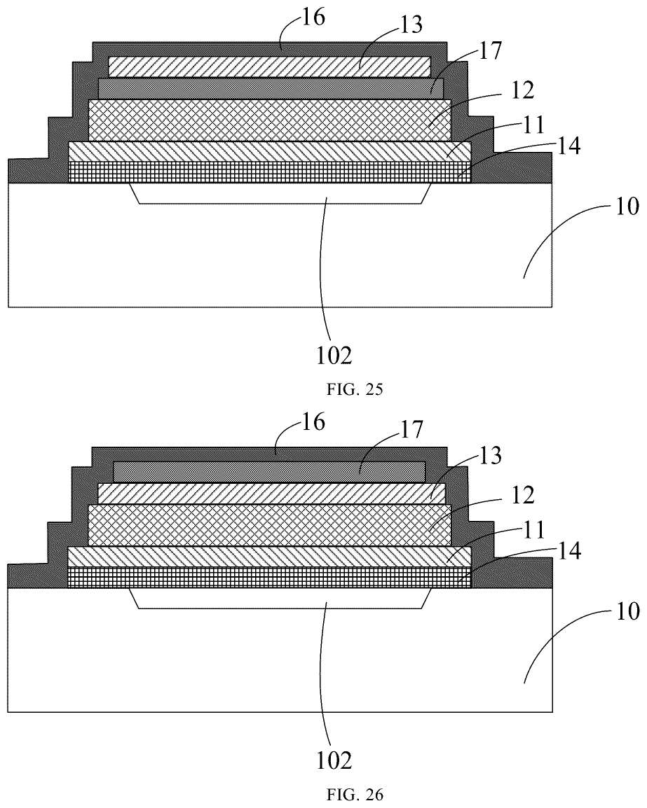

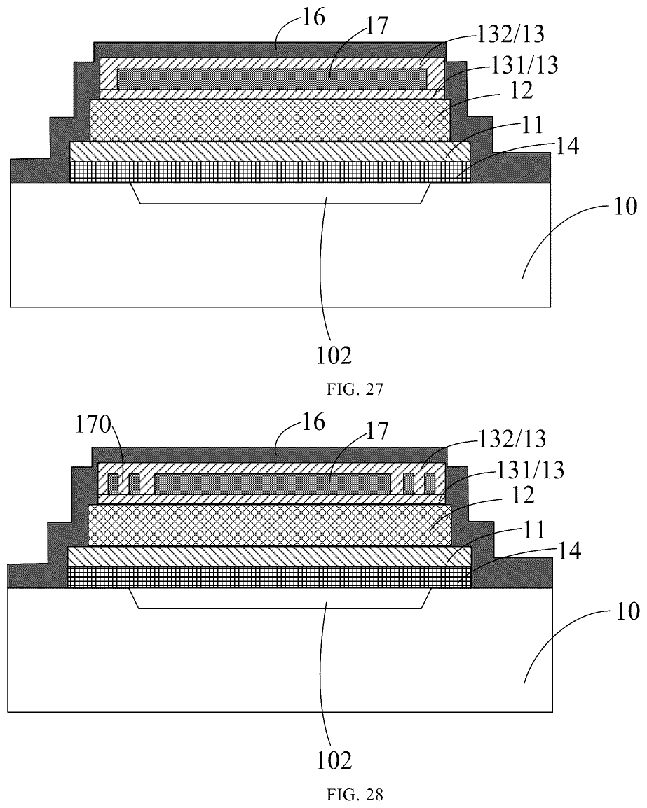

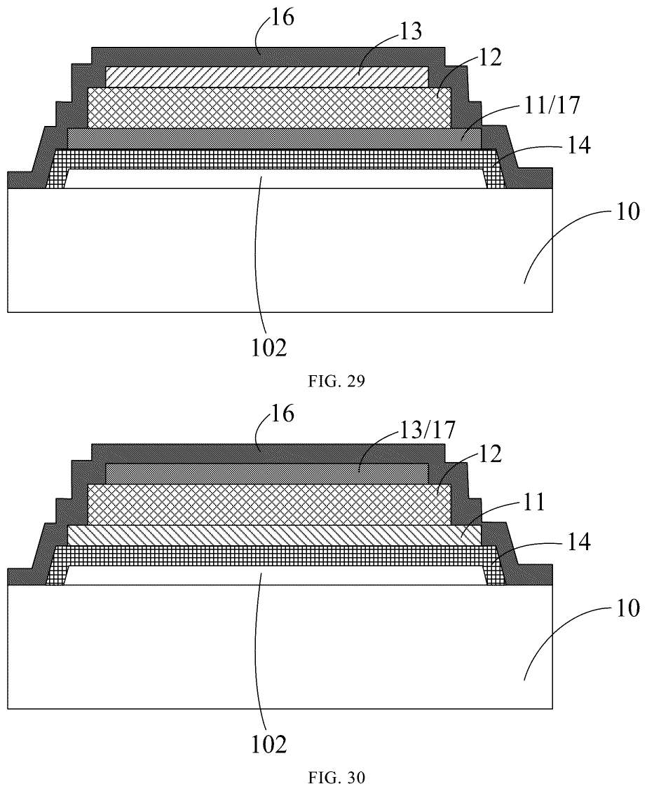

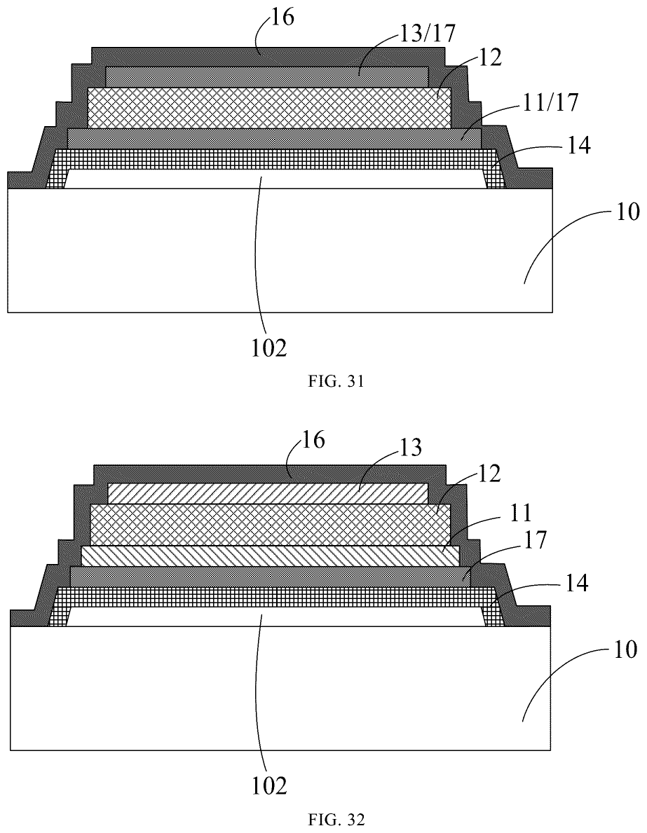

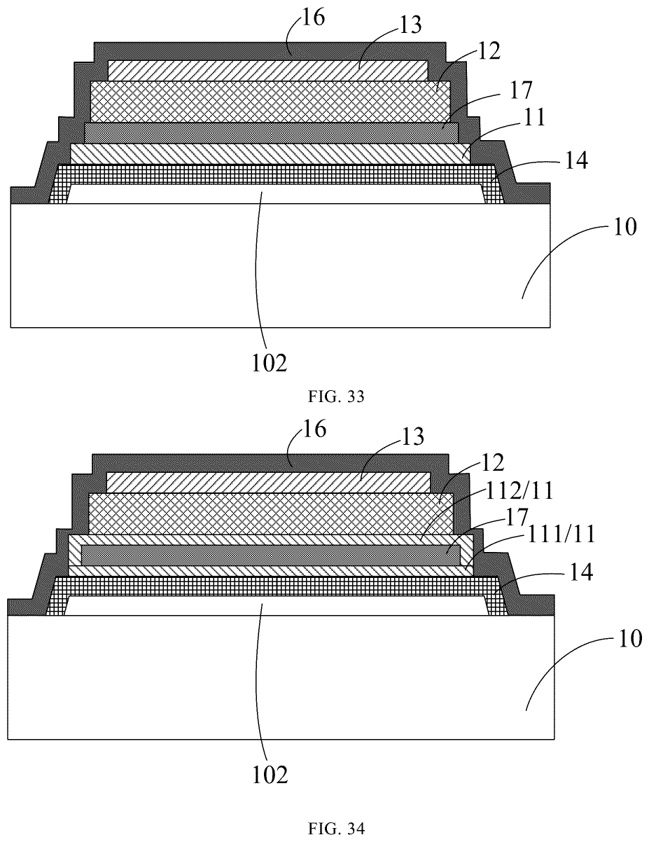

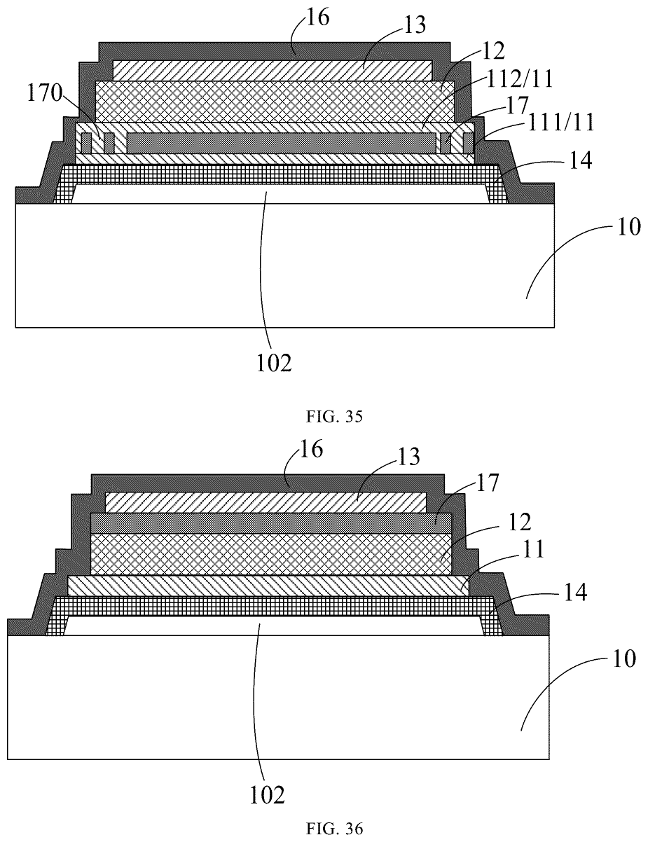

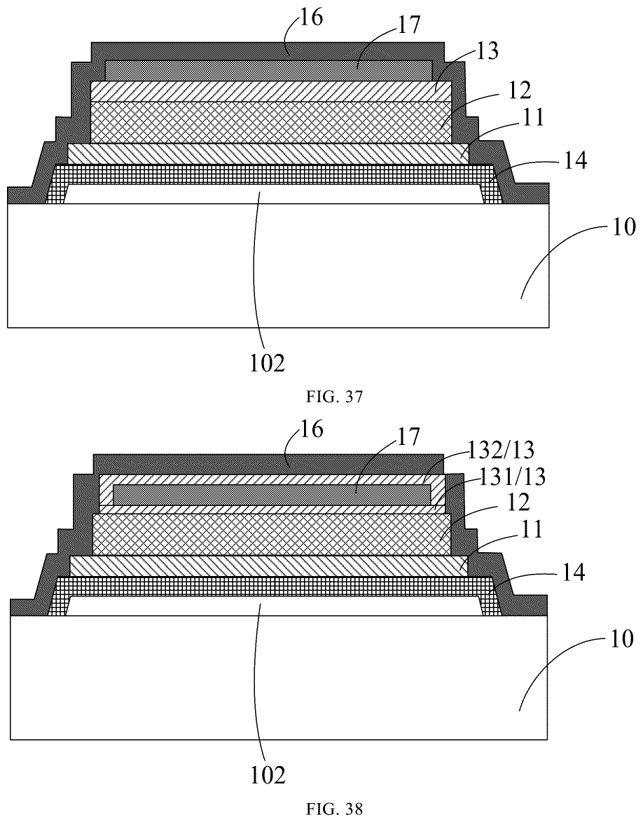

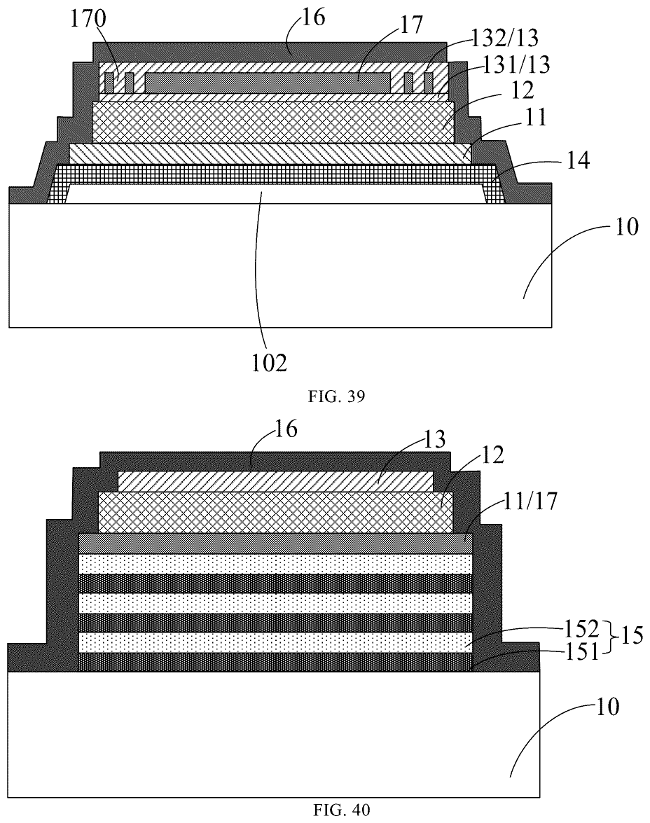

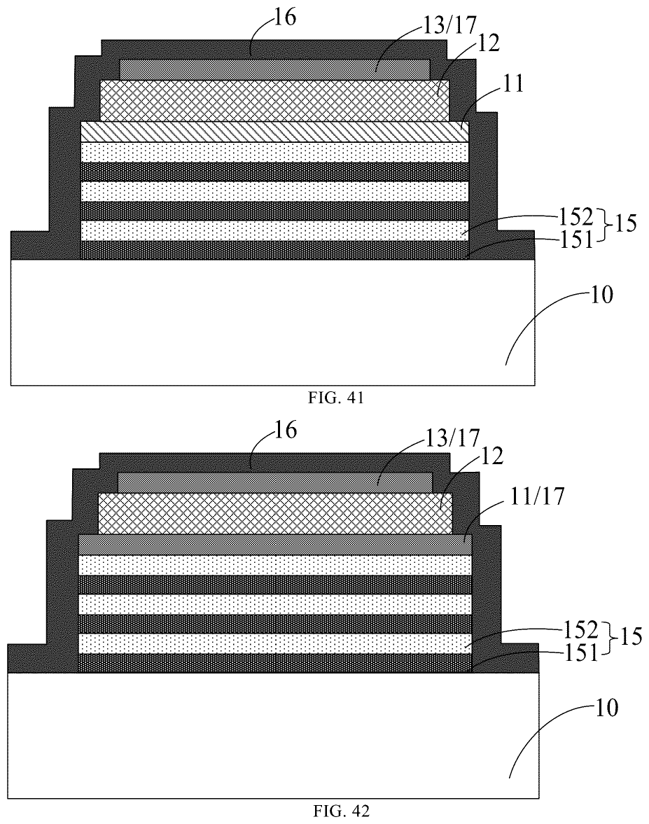

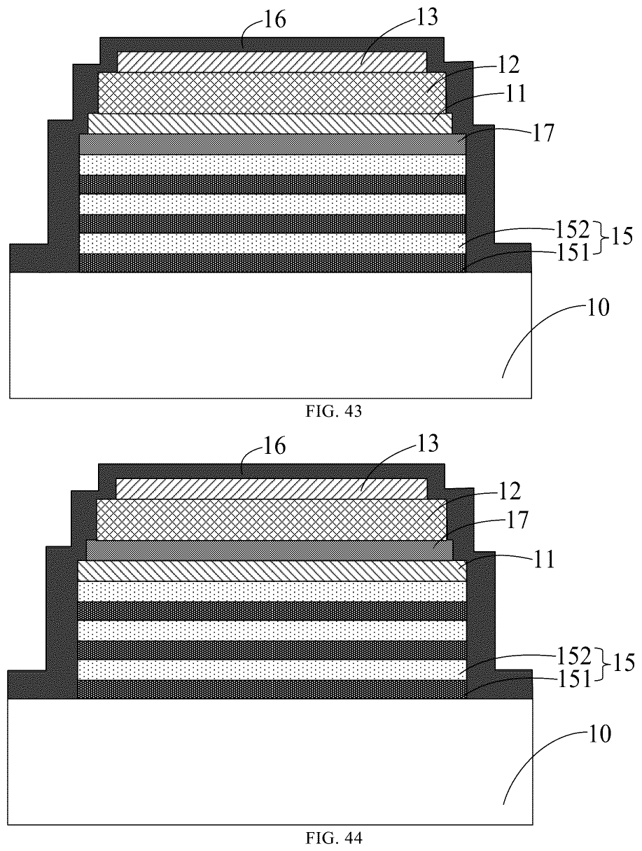

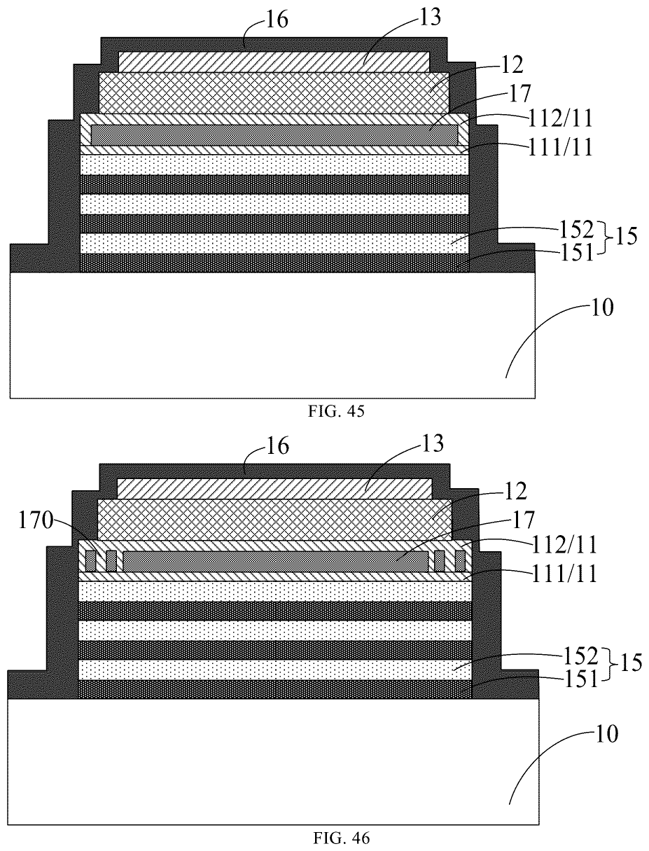

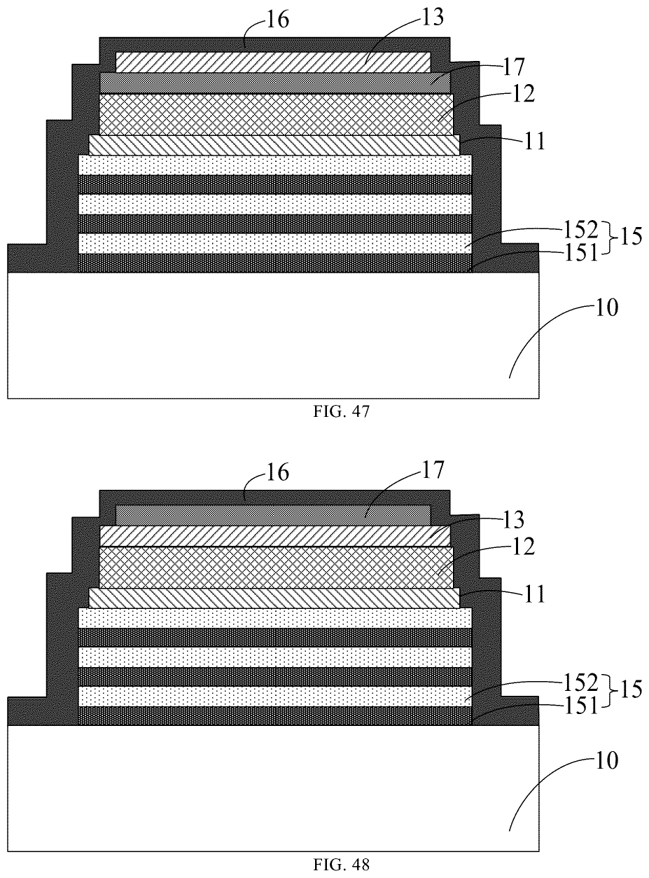

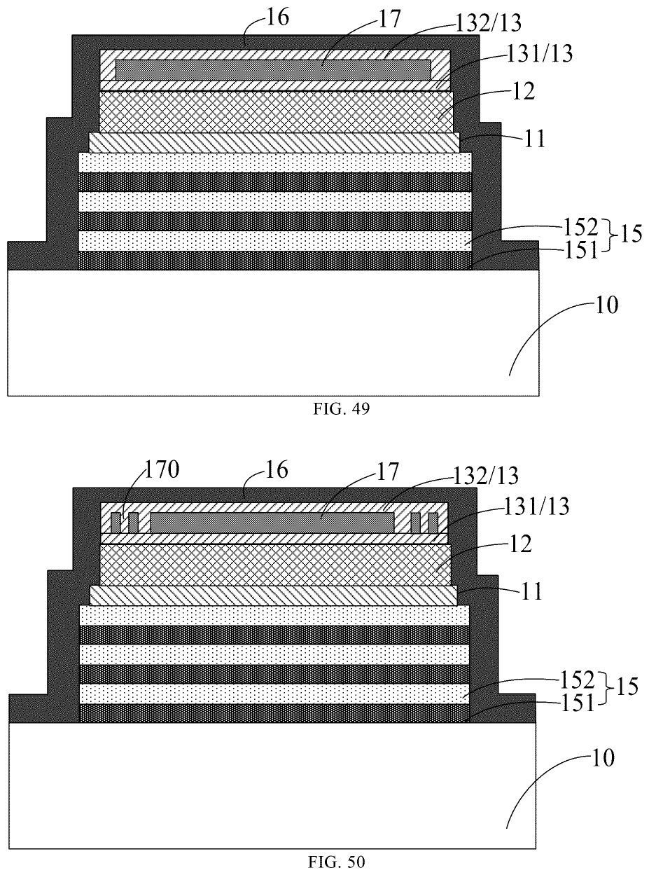

It should be noted that the several exemplary examples of the bulk acoustic wave resonator and the manufacturing method are only given as above, but do not limit the scope of protection of the bulk acoustic wave resonator and the method for manufacturing a bulk acoustic wave resonator in the embodiments of the present disclosure. FIGS. 18 to 50 are schematic diagrams of exemplary bulk acoustic wave resonators according to embodiments of the present disclosure. FIGS. 18 to 28 are schematic diagrams of the bulk acoustic wave resonator according to the embodiment of the present disclosure formed by providing the functional layer 17 in the film bulk acoustic wave resonator shown in FIG. 2a. FIGS. 29 to 39 are schematic diagrams of the bulk acoustic wave resonator according to the embodiment of the present disclosure formed by providing the functional layer 17 in the film bulk acoustic wave resonator shown in FIG. 2b. FIGS. 40 to 50 are schematic diagrams of the bulk acoustic wave resonator according to the embodiment of the present disclosure formed by providing the functional layer 17 in the solid mounted bulk acoustic wave resonator shown in FIG. 3.

The embodiment of the present disclosure further provides an electronic device, which may include the bulk acoustic wave resonator of any one of the above embodiments.

It should be understood that the above embodiments are merely exemplary embodiments adopted to explain the principles of the present disclosure, and the present disclosure is not limited thereto. It will be apparent to one of ordinary skill in the art that various changes and modifications may be made therein without departing from the spirit and scope of the present disclosure, and such changes and modifications also fall within the scope of the present disclosure.

1. A bulk acoustic wave resonator, comprising: a first base substrate, a first electrode, a piezoelectric layer, and a second electrode; wherein the first electrode is on the first base substrate, the piezoelectric layer is on a side of the first electrode away from the first base substrate, and the second electrode is on a side of the piezoelectric layer away from the first electrode; wherein
the bulk acoustic wave resonator further comprises a functional layer on a side of the piezoelectric layer close to the first base substrate and/or on a side of the piezoelectric layer away from the first base substrate; a material of the functional layer comprises a conductive material, and the functional layer is configured to suppress a temperature drift of the bulk acoustic wave resonator.

2. The bulk acoustic wave resonator according to claim 1, wherein the material of the functional layer has a positive temperature coefficient, and is configured such that a temperature drift coefficient of the bulk acoustic wave resonator is in a range from −10 ppm/K to +10 ppm/K.

3. The bulk acoustic wave resonator according to claim 1, wherein the material of the functional layer comprises at least one of antimony, bismuth and gallium.

4. The bulk acoustic wave resonator according to claim 1, wherein the functional layer has a hollowed-out pattern.

5. The bulk acoustic wave resonator according to claim 1, wherein the functional layer is on the side of the piezoelectric layer close to the first base substrate, and the functional layer serves as the first electrode; or
the functional layer is on the side of the piezoelectric layer away from the first base substrate, and the functional layer serves as the second electrode.

6. The bulk acoustic wave resonator according to claim 1, wherein the functional layer is on the side of the piezoelectric layer close to the first base substrate, and the functional layer is between the first electrode and the piezoelectric layer; or
the functional layer is on the side of the piezoelectric layer away from the first base substrate, and the functional layer is located between the second electrode and the piezoelectric layer.

7. The bulk acoustic wave resonator according to claim 1, wherein the functional layer is on the side of the piezoelectric layer close to the first base substrate, and the functional layer is between the first electrode and the first base substrate; or
the functional layer is on the side of the piezoelectric layer away from the first base substrate, and the functional layer is on a side of the second electrode away from the first base substrate.

8. The bulk acoustic wave resonator according to claim 1, wherein the first electrode comprises a first sub-electrode and a second sub-electrode arranged sequentially in a direction away from the first base substrate, and the functional layer is on the side of the piezoelectric layer close to the first base substrate, and the functional layer is between the first sub-electrode and the second sub-electrode.

9. The bulk acoustic wave resonator according to claim 1, wherein the second electrode comprises a third sub-electrode and a fourth sub-electrode arranged sequentially in a direction away from the first base substrate, and the functional layer is on the side of the piezoelectric layer away from the first base substrate, and the functional layer is between the third sub-electrode and the fourth sub-electrode.

10. The bulk acoustic wave resonator according to claim 1, wherein the first base substrate comprises a first cavity penetrating through the first base substrate in a thickness direction of the first base substrate; the first base substrate comprises a first surface and a second surface opposite to each other in the thickness direction of the first base substrate; the first cavity comprises a first opening and a second opening opposite to each other; and the first opening is in the first surface, and the second opening is in the second surface; and an orthographic projection of the first electrode on the second surface covers an orthographic projection of the first opening on the second surface.

11. The bulk acoustic wave resonator according to claim 1, wherein the first base substrate comprises a first groove; the first base substrate comprises a first surface and a second surface opposite to each other in a thickness direction of the first base substrate; the first groove comprises a third opening; and the third opening is in the first surface, the first electrode is on the first surface; and an outline of an orthographic projection of the third opening on the second surface is within an outline of an orthographic projection of the first electrode on the second surface.

12. The bulk acoustic wave resonator according to claim 1, further comprising at least one mirror structure between the first electrode and the first base substrate; wherein each of the at least one mirror structure comprises a first sub-structure layer and a second sub-structure layer sequentially arranged in a direction away from the first base substrate, and an acoustic impedance of a material of the first sub-structure layer is greater than that of a material of the second sub-structure layer.

13. The bulk acoustic wave resonator according to claim 1, further comprising an encapsulation layer on a side of the second electrode away from the first base substrate, wherein the encapsulation layer covers the first electrode, the piezoelectric layer, the second electrode and the functional layer.

14. A method for manufacturing a bulk acoustic wave resonator, comprising: sequentially forming a first electrode, a piezoelectric layer and a second electrode on a first base substrate, wherein orthographic projections of any two of the first electrode, the piezoelectric layer and the second electrode on the first base substrate at least partially overlap with each other; wherein the method further comprises: forming a functional layer on a side of the piezoelectric layer close to the first base substrate and/or on a side of the piezoelectric layer away from the first base substrate; a material of the functional layer comprises a conductive material, and the functional layer is configured to suppress a temperature drift of the bulk acoustic wave resonator.

15. The method for manufacturing a bulk acoustic wave resonator according to claim 14, wherein the material of the functional layer has a positive temperature coefficient, and is configured such that a temperature drift coefficient of the bulk acoustic wave resonator is in a range from −10 ppm/K to +10 ppm/K:
the material of the functional layer comprises at least one of antimony, bismuth and gallium; and
the functional layer has a hollowed-out pattern.

16-17. (canceled)

18. The method for manufacturing a bulk acoustic wave resonator according to claim 14, wherein the method comprises the forming the functional layer on the side of the piezoelectric layer close to the first base substrate; the functional layer and the first electrode are formed by a single patterning process, and the functional layer serves as the first electrode; or
the method comprises the forming the functional layer on the side of the piezoelectric layer away from the first base substrate; the functional layer and the second electrode are formed by a single patterning process, and the functional layer serves as the second electrode.

19. The method for manufacturing a bulk acoustic wave resonator according to claim 14, wherein the method comprises the forming the functional layer on the side of the piezoelectric layer close to the first base substrate, and the forming the functional layer is between the forming the first electrode and the forming the piezoelectric layer; or
the method comprises the forming the functional layer on the side of the piezoelectric layer away from the first base substrate, and the forming the functional layer is between the forming the second electrode and the forming the piezoelectric layer.

20. The method for manufacturing a bulk acoustic wave resonator according to claim 14, wherein the method comprises the forming the functional layer on the side of the piezoelectric layer close to the first base substrate, and the forming the functional layer is before the forming the first electrode; or
the method comprises the forming the functional layer on a side of the piezoelectric layer away from the first base substrate, and the forming the functional layer is after the forming the second electrode.

21. The method for manufacturing a bulk acoustic wave resonator according to claim 14, wherein the forming the first electrode comprises sequentially forming a first sub-electrode and a second sub-electrode in a direction away from the first base substrate; the method comprises the forming the functional layer on the side of the piezoelectric layer close to the first base substrate, and the forming the functional layer is between the forming the first sub-electrode and the forming the second sub-electrode; or
the forming the second electrode comprises sequentially forming a third sub-electrode and a fourth sub-electrode in a direction away from the first base substrate; the method comprises the forming the functional layer on the side of the piezoelectric layer away from the first base substrate, and the forming the functional layer is between the forming the third sub-electrode and the forming the fourth sub-electrode.

22-25. (canceled)

26. An electronic device, comprising the bulk acoustic wave resonator according to claim 1.
